(19) United States
(12) Patent Application Publication
(10) Pub. No.: US 2026/0317898 A1
(43) Pub. Date: Oct. 15, 2026

(54) CYCLIC DEPOSITION OF OXIDES USING WATER AND OZONE

(71) Applicant: Eugenus, Inc., San Jose, CA (US)

(72) Inventors: Sang Young Lee, San Jose, CA (US); Sung-Hoon Jung, Santa Clara, CA (US); Jerry Mack, San Jose, CA (US); Niloy Mukherjee, San Ramon, CA (US)

(21) Appl. No.: 19/176,014

(22) Filed: Apr. 10, 2025

(51) Int. Cl. C23C 16/40; C23C 16/455

(52) U.S. Cl. CPC C23C 16/405; C23C 16/45527

(57) ABSTRACT

The disclosed technology generally relates to a method of forming metal oxides, and more particularly to forming metal oxides using water and ozone. In one aspect, a method of forming a metal oxide by cyclic vapor deposition comprises providing a substrate comprising a surface comprising a metallic or semiconducting material. The method additionally comprises exposing the substrate to a plurality of first exposure cycles each including one or more first metal precursors and H₂O to form a first oxide layer, The method further comprises exposing the substrate to a plurality of second exposure cycles each including one or more second metal precursors and O₃ to form a second oxide layer.

### BACKGROUND

### Field

The disclosed technology generally relates to dielectric and ferroelectric oxides for semiconductor devices, and more particularly to dielectric and ferroelectric oxides having controlled bulk and interfacial defects, and methods of forming the same.

### Description of the Related Art

The need for continued dimensional scaling, improved performance, low temperature integration, voltage/current scaling and/or three-dimensional (3D) integration of semiconductor devices, among other trends, is driving a corresponding need for new and improved materials and synthesis and integration methods thereof. Among various materials, the deposition and integration of dielectric, paraelectric and ferroelectric materials have undergone rapid improvement in recent years, in part enabled by advanced processing technologies for forming these materials for integration with complementary metal-oxide-semiconductor (CMOS) technology.

Dielectric, paraelectric and ferroelectric materials include crystalline and amorphous inorganic compounds such as oxides and nitrides, as well as organic compounds and polymers and find many key applications in CMOS technology. For example, low permittivity dielectrics may be used as insulators, e.g., intermetal dielectrics, in advanced CMOS circuits in order to reduce RC delay and enhance the signal transfer rate across the chips. On the other hand, high permittivity dielectrics may be used in capacitors in dynamic random access memory (DRAM) devices and gate dielectrics in field-effect transistors (FETs), for reduced leakage and effective oxide thicknesses of such dielectrics. Untra thin dielectrics may be used as tunnelling barriers, for example, for spin transfer torque magnetic random access memory (STT-MRAM) devices.

Ferroelectric materials have many properties that are particularly pertinent for CMOS devices. For example, many ferroelectric materials have high dielectric coefficients over a wide temperature and frequency range, and can be integrated in capacitors, e.g., for DRAM, as discussed above. Some ferroelectric materials have large piezoelectric effect and can be used in a variety of electromechanical sensors, actuators and transducers. The significant non-linearities in electromechanical behavior, field tunable permittivities and refractive indices, and electrostrictive effects make ferroelectric materials attractive for many different applications. Of particular interest for ferroelectric materials include memory applications, where the direction of the spontaneous polarization can be used to store digital information.

Some dielectric, paraelectric and ferroelectric materials for CMOS devices may be formed by cyclic deposition processes. Cyclic deposition processes such as atomic layer deposition (ALD) processes can provide a relatively conformal thin films on relatively high aspect-ratio (e.g., 2:1) structures with high uniformity and thickness precision. While generally less conformal and uniform compared to ALD, thin films deposited using continuous deposition processes such as chemical vapor deposition (CVD) can provide higher productivity and lower cost. ALD and CVD can be used to deposit a variety of different films including elemental metals, metallic compounds (e.g., TiN, TaN, etc.), semiconductors (e.g., Si, III-V, etc.), dielectrics (e.g., SiO₂, AlN, HfO₂, ZrO₂, etc.), rare-earth oxides, conducting oxides (e.g., IrO₂, etc.), ferroelectrics (e.g., PbTiO₃, LaNiO₃, etc.), superconductors (e.g., Yba₂Cu₃O₇₋ₓ), and chalcogenides (e.g., GeSbTe), to name a few. Thus, there is a need for improved deposition processes integration approaches for oxides for CMOS integration, including dielectrics, paraelectrics and ferroelectrics.

### SUMMARY

In a first aspect, a method of forming a ferroelectric layer comprising Hf and Zr for a semiconductor device includes exposing a substrate to a plurality of first exposure cycles each including exposures to a Hf precursor, water (H₂O) and a Zr precursor to form a first layer of HfZrO. The method additionally includes exposing the substrate to a plurality of second exposure cycles each including exposures to the Hf precursor, ozone (O₃) and the Zr precursor to form a second layer of HfZrO over the first layer of HfZrO. The first and second layers of HfZrO are formed in situ in a same reactor chamber.

In a second aspect, a method of forming a ferroelectric layer comprising Hf and Zr for a semiconductor device includes cyclically exposing a substrate to a plurality of exposure cycles including exposures to reactants including a Hf precursor, H₂O, O₃, and a Zr precursor to form a layer of HfZrO, wherein at least one of the exposure cycles includes exposures to both H₂O and O₃.

In a third aspect, a method of forming a ferroelectric layer comprising Hf and Zr for a semiconductor device includes providing a substrate in a reactor chamber configured to deliver a Hf precursor, H₂O, ozone, and a Zr precursor, where at least H₂O and ozone are configured to be delivered through separate lines connected to the reactor chamber. The method additionally includes cyclically exposing the substrate to a plurality of exposure cycles including exposures to reactants including a Hf precursor, H₂O, ozone, and a Zr precursor to form a layer of HfZrO.

### BRIEF DESCRIPTION OF THE DRAWINGS

Embodiments of this disclosure will now be described, by way of non-limiting examples, with reference to the accompanying drawings.

FIG. 1 shows a device stack including an oxide formed by a cyclic deposition process.

FIG. 2 schematically illustrates a thin film deposition system configured to deliver O₃ and H₂O as oxidizing precursors, according to embodiments.

FIG. 3A is a flow chart of a method of forming a metal oxide by cyclic deposition, according to some embodiments.

FIG. 3B shows a device stack including an oxide formed by the cyclic deposition method illustrated in FIG. 3A, according to some embodiments.

FIG. 3C schematically illustrates an example precursor delivery sequence for forming the oxide according to the cyclic deposition method illustrated in FIG. 3A, according to embodiments.

FIG. 4A is a flow chart of a method of forming a metal oxide by cyclic deposition, according to some embodiments.

FIG. 4B shows a device stack including an oxide formed by the cyclic deposition method illustrated in FIG. 3A, according to embodiments.

FIG. 4C schematically illustrates an example precursor delivery sequence for forming the oxide according to the cyclic deposition method illustrated in FIG. 4A, according to embodiments.

FIG. 5 is a flow chart of a method of forming a hafnium zirconium oxide (HfZrO) by cyclic deposition, according to some embodiments.

FIGS. 6A and 6B are flow charts of a method of forming a HfZrO by cyclic deposition, according to some embodiments.

FIG. 7A is a graph illustrating experimentally measured, using X-ray photoelectron spectroscopy, HfO concentrations of the HfZrO films grown according to embodiments, as a function of the ratio of the HfO dose to the ZrO dose.

FIG. 7B is a graph illustrating experimentally measured interfacial silicon oxide (e.g., SiO₂) thicknesses as a function of the thickness of the first layer of HfZrO thin films resulting from exposing the substrate to a plurality of first exposure cycles each including exposures to a Hf precursor, H₂O and a Zr precursor, according to embodiments.

FIG. 7C is a graph illustrating experimentally measured remnant polarization as a function of O₃ exposure times for various HfZrO thin films deposited under different oxidant exposure conditions, according to embodiments.

FIG. 7D is a graph illustrating experimentally measured remnant polarization as a function of O₃ exposure times for various HfZrO thin films formed as bilayers and deposited under different oxidant exposure conditions, according to embodiments.

FIG. 8A schematically illustrates a ferroelectric random access memory device including a ferroelectric oxide, according to embodiments.

FIG. 8B schematically illustrates a ferroelectric field effect transistor including a ferroelectric oxide, according to embodiments.

FIG. 8C schematically illustrates a ferroelectric tunnel junction including a ferroelectric oxide, according to embodiments.

### DETAILED DESCRIPTION

Some cyclic deposition processes such as atomic layer deposition (ALD) include alternatingly exposing a substrate to a plurality of precursors to form a thin film. The different precursors can alternatingly at least partly saturate the surface of the substrate and react with each other, thereby forming the thin film in a layer-by-layer fashion. Because of the layer-by-layer growth capability, cyclic deposition processes such as ALD can enable precise control of the thickness and the composition, which in turn can enable precise control of various properties such as conductivity, conformality, uniformity, barrier properties and mechanical strength.

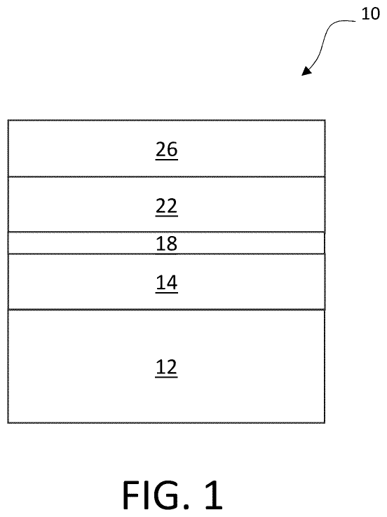

Cyclic deposition processes can be used to form dielectric and ferroelectric oxides by alternatingly exposing a substrate to one or more metal or semiconductor precursors and one or more oxidizing precursors. A typical device structure employing a dielectric, paraelectric or ferroelectric oxide formed by a cyclic deposition process such as ALD can be represented by FIG. 1 illustrates a metal-oxide-metal structure 10 formed on a substrate 12, e.g., a semiconductor substrate. The metal-oxide-metal structure 10 includes a bottom electrode 14 formed over the substrate 12, an oxide 22 formed over the bottom electrode 14 by a cyclic deposition process and a top electrode 16 formed over the oxide 22. The oxide 22 can be formed by cyclically exposing the bottom electrode 14 to one or more metal or semiconductor precursors and one or more oxidizing precursors. Depending on the oxidation strength or oxidation potential, and the diffusivity of the oxidizing precursor, among other factors, forming the oxide 22 by cyclic deposition process can result in formation of an interface layer 18, which can be caused at least in part by oxidization of the bottom electrode 14. For various device applications of the metal-oxide-metal structure 10, the interfacial layer 18 can be detrimental to the performance of the device.

By way of one example, when the oxide 22 serves as a gate dielectric of a metal-oxide-semiconductor (MOS) transistor, e.g., a high k (e.g., k value substantially greater than that of SiO₂) dielectric, the bottom electrode 14 may be a semiconductor material (e.g., Si) and serve to provide a channel, and the top electrode 26 may serve as a gate electrode. Under some fabrication conditions, the interfacial layer 18 can include, e.g., an undesirable lower k oxide having a k value lower than that of the high k dielectric, such as an oxide comprising silicon oxide (e.g., SiOₓ), which can undesirably increase the effective oxide thickness. The increased effective oxide thickness in turn can lead to charge trapping in turn leading to higher threshold voltage, increased leakage current and degradation of the gate control by the channel.

In addition, depending on the oxidation strength and the diffusivity of the oxidizing precursor, among other factors, the oxide 22 may have different concentration of point defects such as oxygen vacancies. Between water and ozone as oxidizing precursors, ozone has higher oxidation strength, and using ozone as the oxidizing precursor generally results in oxides with lower concentration of point defects including oxygen vacancies.

Among oxidizing precursors, ozone (O₃) and water (H₂O) are employed in some cyclic deposition processes. While ozone has a relatively higher oxidation strength and can form oxides with lower concentration of bulk point defects, e.g., oxygen vacancies, cyclic deposition processes employing ozone can detrimentally result in relatively thick interfacial layers. On the other hand, while H₂O has relatively lower oxidation strength and can form relatively thinner interfacial layers, cyclic deposition processes employing H₂O can result in relatively higher concentration of point defects.

### Precursor Delivery System for Cyclic Deposition of Metal Oxides Using Water and Ozone

To address the above-indicated and other needs, the inventors have discovered various inventive aspects that employ water and ozone in an orderly combination of steps as part of cyclic deposition methods. By employing the various inventive aspects disclosed herein, the resulting oxide thin films can synergistically reap the benefits of both water and ozone as oxidizing precursors, while keeping the downsides under control.

To address the above-mentioned needs among others, a thin film deposition system according to embodiments comprises a thin film deposition chamber configured to deposit a thin film by cyclically exposing a substrate to a plurality of exposure cycles including exposures to reactants including one or more metal precursors, H₂O and O₃.

The inventors have discovered various challenges of using water and ozone together in the same cyclic deposition process. For example, the inventors have discovered that H₂O molecules adsorb relatively strongly to various surfaces exposed thereto, including inner surfaces of the delivery line, nozzles, showerhead and chamber walls. As a result, purging H₂O out of the reactor chamber to sufficiently low concentrations can take a very long time, which can in turn greatly reduce productivity. In addition, the inventors have discovered that the concentration of O₃ in the reactor chamber can be greatly reduced by the presence of the residual H₂O, which can result in underdosing of O₃ during growth. Further, O₃ and H₂O can react to form molecular oxygen (O₂) and hydroxyl radicals (OH*), which in turn can lead to further undesirable reactions with various reactor surfaces and/or reactants, as well as the substrate surface. To address these and other challenges of using H₂O and O₃ together in the same chamber, the inventors have discovered, among other things, that delivering ozone and H₂O through separate lines and directly delivering each to the reactor chamber with little or no shared delivery line portions prior to being delivered into the reactor chamber can greatly mitigate such adverse effects. Further, the inventors have discovered that by accounting for the loss of ozone concentration due to residual H₂O, accurate dosing of each can be achieved.

In the following, embodiments may be described using specific precursors for specific films by way examples. For example, specific example metal precursors such as Hf or Zr precursors for forming high k dielectric or ferroelectric layers may be used to describe the thin film deposition system and a method of depositing a thin film according to various embodiments. However, it will be understood that embodiments are not so limited, and the inventive aspects can be applied to any suitable combination of precursors for depositing any suitable thin film that can be formed using cyclic deposition processes such as ALD.

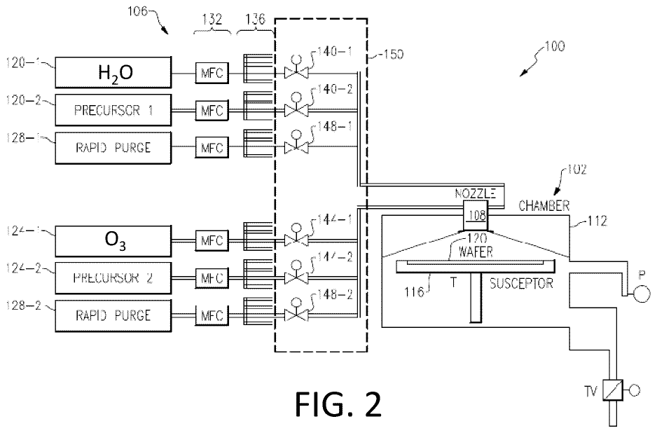

FIG. 2 schematically illustrates a thin film deposition system configured to deliver ozone and H₂O, according to embodiments. The thin film deposition system 100 includes a thin film deposition chamber 102 and a precursor delivery system 106 configured to deliver a plurality of precursors into the deposition chamber 102. The illustrated deposition chamber 102 is configured to process a substrate 120 on a support 116, e.g., a susceptor, under a process condition. The deposition chamber 102 additionally includes a nozzle block 108 configured to centrally discharge the plurality of precursors into the deposition chamber 102 through a gas distribution plate 112, also referred to as a showerhead. The nozzle block 108 may mix the gases, e.g., a precursor and a purge gas, prior to being diffused into the deposition chamber 102 by the gas distribution plate 112. The gas distribution plate 112 is configured to uniformly diffuse the precursor(s) over the substrate 120 on the susceptor 116 so that a uniform deposition occurs. The deposition chamber may be equipped with pressure monitoring sensors (P) and/or temperature monitoring sensors (T).

The precursor delivery system 106 is configured to deliver a plurality of precursors from precursor sources (120, 124) and one or more purge gases, e.g., inert gases, from purge gas sources (128) into the process chamber. Each of the precursors and purge gases is connected to the deposition chamber 102 by a respective gas delivery line. The gas delivery lines additionally include in their paths mass flow controllers (MFCs) 132 and respective precursor valves for introducing respective precursors into the thin film deposition chamber. The gas delivery lines are connected to the deposition chamber 102 through the gas distribution plate 112.

Advantageously, according to various embodiments, the thin film deposition system 100 is configured such that at least one of the precursors can be introduced into the deposition chamber 102 by independently actuating two or more first atomic layer deposition (ALD) valves connected in parallel to the gas distribution plate 112 for supplying the one of the precursors into the thin film deposition chamber 102.

For illustrative purposes only, in the illustrated configuration shown in FIG. 2, the plurality of precursors include a first metal (M1) precursor stored in a M1 precursor source 120-2 and a second metal (M2) precursor stored in a M2 precursor source 124-2. The plurality of precursors additionally include H₂O stored in a H₂O source 120-1 and O₃ generated in an ozone source 124-1. A purge gas can be stored in at least two purge gas sources 128-1, 128-2. H₂O and O₃ are configured to be delivered from the H₂O and ozone sources 120-1, 120-2, respectively, by independently actuating two respective ALD valves 140-1, 140-2 that are connected to the common gas distribution plate 112 via separate gas lines. Additionally, the M1 and M2 precursors are configured to be delivered from the M1 and M2 precursor sources 120-2, 124-2 by independently actuating two respective ALD valves 140-2, 144-2 that are connected in parallel to the common gas distribution plate 112. Additionally, the purge gas is configured to be delivered from the purge gas sources 128-1, 128-2 by independently actuating two respective purge gas ALD valves 148-1, 148-2 that are connected in parallel to the common gas distribution plate 112. The ALD valves 140-1, 140-2, 144-1, 144-2, 148-1 and 148-2 and the respective delivery lines connected to the gas distribution plate 112 can be arranged to feed the respective gases into the nozzle block 108, which may be attached to a lid of the deposition chamber 102. In the illustrated configuration, the ALD valves 140-1, 140-2, 144-1, 144-2, 148-1 and 148-2 may be final valves before the respective gases are introduced into the deposition chamber 102.

As configured, the thin film deposition system 100 is configured to deliver H₂O and ozone separately through separate gas lines and using independently controlled respective ALD valves. Thus, prior to being introduced into the chamber 102 through the nozzle block 108, H₂O and ozone do not substantially share common delivery line portions or an ALD valve.

By using the thin film deposition system 100 illustrated in FIG. 2 to alternatingly expose the substrate to M1, M2, H₂O and ozone, M1 oxide, M2 oxide and M1M2 oxide can be formed, which represent oxides of M1, M2 and M1 and M2, respectively. By way of example only, the M1 and M2 precursors can include a Hf precursor and a Zr precursor, respectively, that are delivered into the deposition chamber 102 from respective M1 and M2 precursor sources 120-2, 124-2 through respective precursor delivery lines, to form HfZrO, (e.g., HfZrO₂), by alternating with one or both of H₂O and ozone. The precursor delivery system 100 can additionally be configured to deliver Ar as the purge gas into the process chamber from Ar sources through purge gas delivery lines. Purge gases may be delivered as a continuous purge (CP) gas, which may be delivered through precursor ALD valves, and/or as a rapid purge (RP) gas, which may be delivered through dedicated purge gas ALD valves as shown in FIG. 2. The illustrated precursor delivery system 100 can be configured to deliver Ar as an RP gas into the process chamber 102 from the purge gas sources 128-1, 128-2 through respective purge gas delivery lines and purge gas ALD valves 148-1, 148-2.

Still referring to FIG. 2, according to various embodiments, the thin film deposition system 100 is configured for thermal cyclic vapor deposition such as ALD without an aid of plasma. While plasma-enhanced processes such as plasma enhanced atomic layer deposition (PE-ALD) may be effective in forming conformal films on surfaces having relatively low aspect ratios, such processes may not be effective in depositing films inside vias and cavities having relatively high aspect ratios. Without being limited by theory, one possible reason for this is that plasma may not reach deeper portions of high aspect ratio vias under some circumstances. In these circumstances, different portions of the vias may be exposed to different amounts of the plasma, leading to undesirable structural effects arising from non-uniform deposition, such as thicker films being deposited near the opening of the via compared to deeper portions (sometimes called cusping or keyhole formation). For these reasons, a thermal cyclic vapor deposition such as thermal ALD may be more advantageous, because such thermal processes do not depend on the ability of the plasma to reach portions of the surface being deposited on.

Furthermore, for various applications of oxides, using plasma-assisted cyclic deposition processes can have deleterious effects such as plasma-induced defects. By one example, when the deposited oxide serves as a gate dielectric, the defects can serve as charge trap centers to shift threshold voltages of transistors or provide traps centers that form a leakage current path. Further, when the deposited oxide serves as an insulator of a capacitor, the defects can result in capacitor leakage and electrostatic discharge events.

To address the above-indicated and other needs, the inventors have discovered various inventive aspects that employ water and ozone in an orderly combination of steps as part of cyclic deposition methods. By employing the various inventive aspects disclosed herein, the resulting oxide thin films can synergistically reap the benefits of using both water and ozone as oxidizing precursors.

### Metal Oxide Formation by Sequential Cyclic Deposition of Sublayers Using Water Followed by Ozone

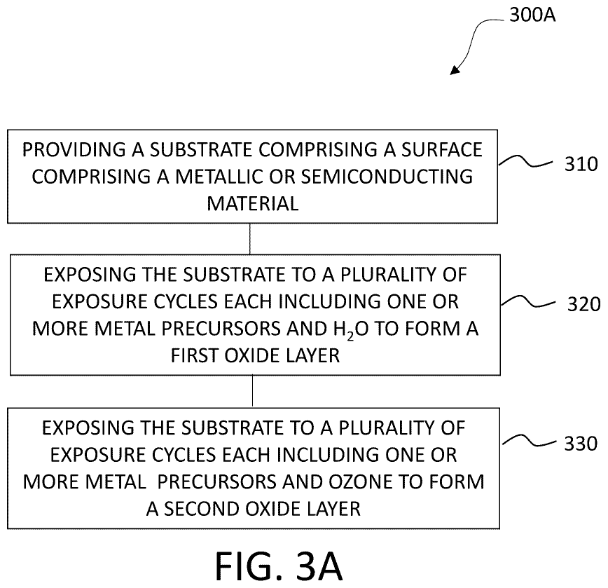

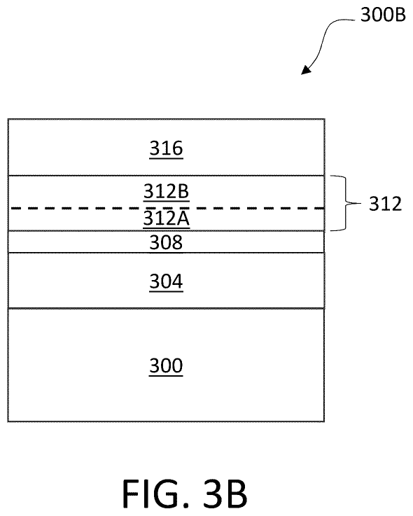

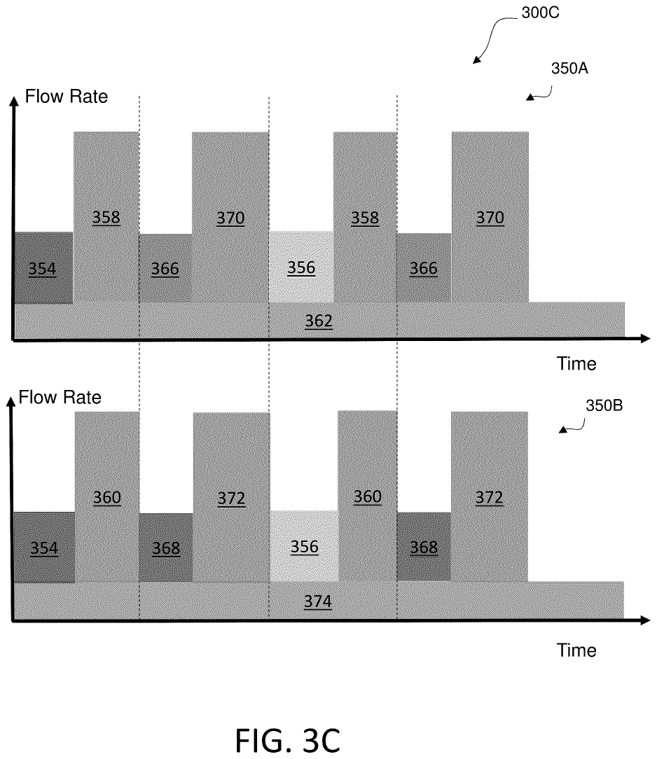

In a first inventive aspect that employs water and ozone in an orderly combination of steps as part of a cyclic deposition process, methods include sequential deposition of sublayers, where the first sublayer employs water (H₂O) as the oxidizing precursor and the second sublayer employes (O₃) ozone as the oxidizing precursor. FIG. 3A is a flow chart illustrating a method 300A of forming a metal oxide by cyclic deposition, according to embodiments. FIG. 3B shows a device stack 300B including the metal oxide formed by the method illustrated in FIG. 3A. FIG. 3C schematically illustrates an example precursor delivery sequence 300C for forming the metal oxide according to the method illustrated in FIG. 3A. In the following, the method 300A (FIG. 3A) according to embodiments is described in conjunction with the device stack 300B (FIG. 3B) and the precursor delivery sequence 300C (FIG. 3C).

The method 300A includes providing 310 a substrate comprising a surface comprising a metallic or semiconducting material. The method 300A additionally includes exposing 310 the substrate to a plurality of exposure cycles each including one or more metal precursors and H₂O to form a first oxide layer. The method 300A further includes exposing 320 the substrate to a plurality of exposure cycles each including one or more metal precursors and O₃ to form a second oxide layer.

Cyclic deposition processes such as atomic layer deposition (ALD) can provide relatively conformal thin films on relatively high aspect-ratio (e.g., 2:1) structures with high uniformity of the thickness with precision. Thin films deposited using continuous deposition processes such as chemical vapor deposition (CVD) are generally less conformal and uniform. According to embodiments, the spaces in which conformal layers can be formed can have a width less than 20 nm, 15 nm, 10 nm, 5 nm or a value in a range defined by any of these values, and have aspect ratios greater than 2, 5, 10, 20 or a value in a range defined by any of these value. In particular, the cyclic deposition processes according to embodiments are thermal cyclic deposition processes that rely on a chemical reaction between precursors that are thermally driven without aid of a plasma.

Cyclic deposition processes including atomic layer deposition (ALD) according to embodiments include alternatingly exposing a substrate to a plurality of precursors to form a thin film in a layer-by-layer fashion, to precisely control such properties of the thin film as conformality, uniformity, stress and barrier properties (e.g., with respect to oxygen, moisture and various other impurities). The reactants or precursors can include oxidizing and reducing reactants that are alternatingly introduced into a reaction chamber having disposed therein a substrate. The introduction of one or more reactants or precursors may be in turn be alternated with a purge and/or a pump out process for removing excess reactants or precursors from the reaction chamber. The precursors or reactants may be introduced into the reaction chamber under a condition over a suitable period of time such that the surface on which the encapsulation layer is to be deposited can become at least partly saturated, e.g., substantially entirely saturated, with the precursors or reactants and/or a reaction product of the reactants. Excess or residual precursors or reactants may then be purged and/or pumped out of the reaction chamber. A pump out process may be performed by a suitable vacuum pumping process and a purge step may be performed by introducing a non-reactive or an inert gas, e.g., nitrogen or a noble gas, into the reaction chamber.

As described herein and throughout the specification, it will be appreciated that the semiconductor substrate over which the metal oxide is formed can be implemented in a variety of substrates, including, but not limited to, a doped semiconductor substrate, which can be formed of an elemental Group IV material (e.g., Si, Ge, C or Sn) or an alloy formed of Group IV materials (e.g., SiGe, SiGeC, SiC, SiSn, SiSnC, GeSn, etc.); Group III-V compound semiconductor materials (e.g., GaAs, GaN, InAs, etc.) or an alloy formed of Group III-V materials; Group II-VI semiconductor materials (CdSe, CdS, ZnSe, etc.) or an alloy formed of Group II-VI materials.

According to certain embodiments, the substrate can also be implemented as a bulk semiconductor substrate or a semiconductor on insulator, such as silicon on insulator (SOI) substrate. An SOI substrate typically includes a silicon-insulator-silicon structure in which the various structures described above are isolated from a support substrate using an insulator layer such as a buried SiO₂ layer (BOX). In addition, it will be appreciated that the various structures described herein can be at least partially formed in an epitaxial layer formed at or near a surface region.

According to various embodiments, the substrate over which the metal oxide according to embodiments is formed can include various intermediate structures of a semiconductor device. The intermediate structures can include, e.g., at least portions of active devices such as transistors and diodes and/or passive devices such as capacitors and resistors. For example, the metal oxide according to embodiments can be formed over a substrate as part of a capacitor having a device stack 300B illustrated in FIG. 3B. Referring to FIG. 3B, the metal oxide 312 may be formed over a substrate 300 having formed thereon a bottom electrode 304. The metal oxide 312 may be, e.g., a dielectric, paraelectric or ferroelectric oxide formed by a cyclic deposition process such as ALD according to the method illustrated in FIG. 3A. For example, depending upon the adjacent materials, suitable electrode materials for the bottom electrode 304 (and/or the top electrode 316) can include one or more conductive and semiconductive materials such as, for example, carbon (C); n-doped polysilicon and p-doped polysilicon; metals including, Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; and conductive metal oxides including RuO₂.

Still referring to FIGS. 3A and 3B, when the metal oxide 312, which can include first and second metal oxides 312A, 312B, which can constitute sublayers of the metal oxide 312, serves as a high k dielectric for a field effect transistor, the metal oxide 312 may be deposited on a semiconductor channel comprising a doped semiconductor serving as the bottom electrode 304. According to various embodiments, the metal oxide 312 can include a suitable gate dielectric material, which in turn includes an oxide such as, but not limited to, SiO₂, Ta₂O₅, SrTiO₃, ZrO₂, HfO₂, Al₂O₃, La₂O₃, Y₂O₃, HfSiO₄, LaAIO₃. MgO, CeO₂, Er₂O₃, Nd₂O₃, Pr₂O₃, Dy₂O₃, Gd₂O₃, La₂O₃, Y₂O₃, Sc₂O₃, SrTiO₃, LaLuO₃, LaScO₃, GdScO₃, DyScO₃, or combinations thereof, including mixtures and nanolaminates thereof. Referring to FIG. 3B, one or both of the first and second metal oxides 312A, 312B can include any of these oxides, and referring to FIG. 3A, the one or more metal precursors can include the metal of any one of these metal oxides.

Still referring to FIGS. 3A and 3B, when the metal oxide 312 serves a high k dielectric for a DRAM capacitor, the metal oxide 312, including one or both of first and second metal oxides 312A, 312B, may be deposited on the bottom electrode 304 serving as a capacitor electrode. According to various embodiments, the metal oxide 312 can include a suitable high k oxide material, which in turn includes an oxide such as, but not limited to, SiO₂, Ta₂O₅, SrTiO₃, ZrO₂, HfO₂, Al₂O₃, La₂O₃, Y₂O₃, HfSiO₄, LaAlO₃. MgO, CeO₂, Er₂O₃, Nd₂O₃, Pr₂O₃, Dy₂O₃, Gd₂O₃, La₂O₃, Y₂O₃, Sc₂O₃, SrTiO₃, LaLuO₃, LaScO₃, GdScO₃, DyScO₃, or combinations thereof, including mixtures and nanolaminates thereof. Referring to FIG. 3B, one or both of the first and second metal oxides 312A, 312B can include any of these oxides, and referring to FIG. 3A, the one or more metal precursors can include the metal of any one of these metal oxides.

Still referring to FIGS. 3A and 3B, when the device stack 300B serves a ferroelectric capacitor for a ferroelectric random access memory (FeRAM), the metal oxide 312 may be deposited on the bottom electrode 304 serving as a ferroelectric capacitor electrode. According to some embodiments, the metal oxide 312 can include a suitable ferroelectric material having a perovskite structure, which in turn includes a base metal oxide having a chemical formula ABO₃, wherein each of A and B represents one or more metal elements occupying interchangeable atomic positions of a crystal structure. For example, the metal oxide may include BiFeO₃, BaTiO₃, PbTiO₃, PbZrO₃, KNbO₃, LiNbO₃, (Ba, Sr)TiO3, PbZrTiO₃, or combinations thereof, including mixtures and nanolaminates thereof. According to various other embodiments, the metal oxide 312 can include a suitable transition metal-based ferroelectric materials, such as HfO₂ and ZrO₂ or combinations thereof, including mixtures and nanolaminates thereof. Referring to FIG. 3B, one or both of the first and second metal oxides 312A, 312B can include any of these oxides, and referring to FIG. 3A, the one or more metal precursors can include the metal of these metal oxides.

FIG. 3C schematically illustrates an example precursor delivery sequence for forming the metal oxide illustrated in FIG. 3B using the method illustrated in FIG. 3A, according to embodiments. Referring to FIG. 3C, a precursor delivery sequence for the cyclic deposition or ALD according to embodiments comprises a plurality of first cycles 350A and a plurality of second cycles 350B. The first cycles 350A can correspond to exposing 320 (FIG. 3A) the substrate to a plurality of exposure cycles each including one or more metal precursors to form the first metal oxide 312A (FIG. 3B). In the illustrated embodiment in FIG. 3C, each of the first cycles 350A in turn includes an exposure 354 of the substrate to a first metal (M1) precursor, an exposure 366 to H₂O, an exposure 356 of the substrate to a second metal (M2) precursor, and an exposure 366 to H₂O. Similarly, the second cycles 350B can correspond to exposing 330 (FIG. 3A) the substrate to a plurality of exposure cycles each including one or more metal precursors to form the second metal oxide 312B (FIG. 3B). In the illustrated embodiment in FIG. 3C, each of the second cycles 350B in turn includes an exposure 354 of the substrate to the first metal (M1) precursor, an exposure 368 to O₃, an exposure 356 of the substrate to the second metal (M2) precursor, and an exposure 368 to O₃. Without limitation, referring back to FIG. 2, in one implementation and without limitation, the first cycles 350A may be performed through a first ALD precursor delivery line, and the second cycles 350B may be performed through a second ALD precursor delivery line to suppress the interaction (e.g., reduction of O₃ concentration by H₂O) between surface adsorbed H₂O and O₃.

In the illustrated embodiment of FIG. 3C, the first and second metal precursors may be different for forming a mixed oxide. By way of example, when the metal oxide 312 comprises hafnium zirconium oxide (HZO), the exposure 354 to the M1 precursor may be an exposure to a Hf precursor and the exposure 356 to the M2 precursor may be an exposure to a Zr precursor. However, embodiments are not so limited and in some other embodiments, the first and second metal precursors may be the same within one or both of first and second cycles 350A, 350B. In these embodiments, a single metal oxide 312 such as HfO₂ or ZrO₂ may be formed as a bilayer of first and second metal oxides 312A, 312B formed using H₂O and O₃, respectively.

In some embodiments, one or both of the first cycles 350A and the second cycles 350B include a respective continuous purge 362, 374 using an inert gas, e.g., Ar or N₂. While not illustrated in FIG. 2, the continuous purge may be performed using separate gas sources and lines.

In some embodiments, one or both of the first and second cycles 350A, 350B comprise respective rapid purges 358, 360 using an inert gas following the exposures 354, 356 to first and second metal precursors, respectively. The first and second metal precursors can be delivered using, e.g., a first metal (M1) precursor stored in a M1 precursor source 120-2 and a second metal (M2) precursor stored in a M2 precursor source 124-2 (FIG. 2). The rapid purges can be performed using, e.g., purge gas sources 128-1, 128-2 (FIG. 2).

The inventors have discovered that relatively higher total or partial pressures of precursors inside during exposures can improve step coverage of the metal oxides according to embodiments. According to embodiments total or partial pressures of any of the individual precursors during exposing the substrate during a given subcycle (e.g., M1, M2, H₂O, ozone), may be 1.0-3.0 torr, 3.0-5.0 torr, 5.0-7.0 torr, 7.0-9.0 torr, 9.0-11.0 torr, 11.0-13.0 torr, 13.0-15.0 torr, or a pressure in range defined by any of these values. Each of the precursors can be present in the reaction chamber with an inert gas. In each of the exposures, the respective precursor can make up 1-2%, 2-5%, 5-10%, 10-20%, 20-50%, 50-100% of the total amount of gas molecules in the reaction chamber, or a percentage in a range defined by any of these values. The inventors have discovered that, under some circumstances, when the total or partial pressure is outside of these values, step coverage may start to degrade, among other potential negative effects.

The inventors have discovered that, in part to enable relatively high throughput while delivering relatively high amounts of precursors to the reaction chamber for deposition at relatively high total or partial pressures, the flow rates of the precursors into the reaction chamber should be significantly higher than those used in process conditions for forming thin films on planar substrates and/or substrates with low (e.g., <1) aspect ratio structures. It will be appreciated that the relatively high flow rate to achieve various advantages described herein can depend on, among other things, the pumping rate, exposure time, and volume of the reactor. To achieve flow rates adapted for depositing the thin film on substrates having a high surface area and/or high aspect ratio structures, the temperature and or pressure of the precursor, among other parameters, can be adjusted such that the flow rate of each of the precursors and/or purge gas can be, e.g., 100-1000 standard cubic centimeters per minute (sccm), 1000-2000 sccm, 2000-5000 sccm, 5000-10,000 sccm, 10,000-15,000 sccm, 15,000-20,000 sccm, or a value in a range defined by any of these values or higher. It will be appreciated that a suitable flow rate can depend, among other things, the volume of the reactor, and some of these flow rates may be suitable for single wafer reactors having a volume of about 1-2 liters.

According to embodiments, the exposure time of each of the precursors can be less than 30 sec., 20 sec., 10 sec., 5 sec., 1.0 sec., 0.8 sec., 0.6 sec, 0.4 sec, 0.2 sec., 0.1 sec., 0.05 sec., 0.01 sec. or a value in a range defined by any of these values. The thin film deposition system is configured to introduce the precursors through respective ones of the precursor delivery lines according to embodiments at flow rates such that a surface of the substrate substantially reaches a saturation level, e.g., a saturation level greater than 40%, 60%, 80% or a value in a range defined by any of these values, within the exposure time. In embodiments where a rapid purge follows an exposure to a precursor, durations of one or both of the first and second cycles 350A, 350B can be less than 1.0 sec., 0.8 sec., 0.6 sec, 0.4 sec, 0.2 sec., 0.1 sec., 0.05 sec., 0.01 sec., or a value in a range defined by any of these values.

One or both of the first and second cycles 350A, 350B can additionally comprise respective rapid purges 370, 372 using an inert gas following the exposures 366, 368 to H₂O and O₃, respectively. H₂O and O₃ can be delivered using, e.g., H₂O stored in a H₂O source 120-1 and O₃ is generated in an ozone source 124-1 (FIG. 2). The rapid purges 358, 360, 370, 372 may be performed at higher flow rates than those of the continuous purges 362, 374. In some other embodiments, one or both of the continuous purge and the rapid purge may be omitted from one or both of the first and second cycles 350A, 350B. In these embodiments, instead of a rapid purge, the precursors may be pumped out without a purge gas flowing into the reactor.

Thus, according to various embodiments, referring to FIGS. 3A-3C, in the method 300A (FIG. 3A), exposing 320 the substrate to a plurality of exposure cycles can include exposing the substrate to N number (1 or greater) of first cycles 350A (FIG. 3C) each including exposures to one or more metal precursors (M1 and/or M2) and H₂O to form the first metal oxide 312A (FIG. 3B). In addition, in the method 300A, exposing 330 the substrate to a plurality of exposure cycles can include exposing the substrate to M number (1 or greater) of second cycles 350B (FIG. 3C) each including exposures to one or more metal precursors (M1 and/or M2) and O₃ to form the second metal oxide 312B (FIG. 3B). The compositions of the first and second metal oxides 312A, 312B may be about the same or different, depending on the particular deposition conditions.

Each exposure to the one or more metal precursors is such that, after an exposure, the substrate surface can become substantially or partly saturated with the metal precursor. After exposing the substrate to each of the one or more metal precursors, excess or residual metal precursor and/or its reaction products that do not remain adsorbed or chemisorbed on the surface of the substrate may be removed from the substrate surface, such as by having the process chamber pumped and/or purged out. Each exposure to the water or ozone is such that, after exposure, the substrate surface can become substantially or partly saturated with the water or ozone. After exposing the substrate to the water or ozone, excess or residual water or ozone or its reaction products that do not remain adsorbed or chemisorbed on the surface of the substrate may be removed from the substrate surface, such as by having the process chamber pumped or purged out. Subjecting the substrate to one or more first or second cycles 350A or 350B may form one or more monolayers or a region formed substantially of first or second metal oxides 312A, 312B.

In some embodiments, the exposure to the one or more metal precursors in a given one of first or second cycles 350A, 350B may be performed a plurality of times in sequence. Similarly, the exposure to the water or ozone in a given one of first or second cycles 350A, 350B, may be performed a plurality of times in sequence. Advantageously, under some circumstances, exposing the substrate to a metal or water or ozone more than once may result in a higher level of surface saturation, e.g., when substantial stearic hindrance effect exists, by exposing more reactive sites for the respective precursor adsorption.

It will be appreciated that, in various embodiments, the frequency and number of repetition of the first cycles 350A and the frequency and number of repetition of the second cycles 350B, the frequency and the number of repetition of the exposures of the substrate to each of the one or more metal precursors during each of the first and second cycles 350A, 350B, and the frequency and the number of repetition of the exposures of the substrate to the water or ozone during the first and second cycles 350A, 350B, respectively, as described herein, can be varied to obtain a desired thickness, stoichiometry and other properties described herein in the resulting metal oxide layer, based on various considerations including susceptibility to stearic hindrance effects of the precursors.

As described above, the inventors have found that, while ozone has relatively higher oxidation strength and can form oxides with lower concentration of bulk point defects, employing ozone can result in relatively thicker interfacial layers. On the other hand, while H₂O has a relatively lower oxidation strength and can form relatively thinner interfacial layers, employing H₂O can result in relatively higher concentration of point defects. In the method illustrated in FIGS. 3A and 3B, by first forming the first metal oxide 312A to a suitable first thickness using H₂O, the thickness of the interfacial layer 308 (FIG. 3B) can be reduced. In addition, by controlling the thickness and growth conditions of the subsequent formation of the second metal oxide 312B using ozone, the overall concentration and profile of bulk point defects can be tuned, e.g., reduced, for a particular purpose. It will be appreciated that, for some applications, some concentration of point defects may be beneficial, e.g., for forming ferroelectric phases of HZO. Similarly, for some applications, some thickness of interfacial layer 308 may be beneficial.

Under some circumstances, the first and second metal oxides 312A, 312B can be distinguished, depending on the respective growth conditions, even if the same metal precursors are used to form them. For example, the second metal oxide 312B grown with ozone may have slightly higher oxygen content (corresponding to lower oxygen vacancy concentration) and slightly lower OH content.

Non-limiting examples of precursors that can be used to form various hjgh k dielectric, paraelectric and ferroelectric metal oxides include the following.

Non-limiting examples of a Sr precursor include bis (2,2,6,6-tetramethyl-3,5-heptanedionate) strontium (“Sr(tmhd)₂”) to name a few.

Non-limiting examples of La precursor include tris-isopropylcyclopentadienyl lanthanum (“La(iPrCp)₃”), lanthanum tris-formamidinate (“La(fAMD)₃”), and tris (2,2,6,6-tetramethyl-3,5-heptanedionate) lanthanum (“La(tmhd)₃”) to name a few.

Non-limiting examples of a Ti precursor include TiCl₄, StarTi, tetrakis-dimethylamino titanium (“TDMAT”), tetrakis-diethylamino titanium (“TDEAT”), tetrakis-ethylmethylamino titanium (“TEMAT”), titanium tetrakis-isopropoxide (“TTIP”), titanium methoxide, titanium ethoxide, titanium t-buthoxide, chlorotriisopropoxytitanium, titanium 2-ethylhexyloxide and titanium oxyacetylacetonate.

Non-limiting examples of a Ta precursor include tertiary-butyl imido tris-diethyl tantalum (“TBTDETa”), and tertiary-butyl imido tris-ethylmethylamino tantalum (“TBITEMATa”), to name a few.

Non-limiting examples of a Mg precursors include bis-ethylcyclopentadienyl magnesium (“Mg(CpEt)₂”), tetra(2,2,6,6-tetramethyl-3,5-heptanedionate) magnesium (“Mg₂(tmhd)4”), and Mg(tmhd)₂(EtOH)₂, to name a few, where tmhd=2,2,6,6-tetramethyl-3,5-heptanedionate.

Non-limiting examples of a Ce precursor include Ce(iPrCp)₃, Ce(tmhd)₄ and Ce(tmhd)₃phen, where iPrCp=isopropylcyclopentadienyl, tmhd=2,2,6,6-tetramethyl-3,5-heptanedionate, phen=1,10-phenanthroline, to name a few.

Non-limiting examples of a Gd precursor include tris(2,2,6,6-tetramethyl-3,5-heptanedionate) gadolinium (“Gd(tmhd)₃”), tris-isopropylcyclopentadienyl gadolinium (“Gd(iPrCp)₃”), (tris(2,3-dimethyl-2-butoxy)gadolinium(III)) (“Gd[OC(CH₃)₂CH(CH₃)₂]₃”), and Gd(CpCH₃)₃, where Cp=cyclopentadienyl (C₅H₅).

A non-limiting example of a Dy pre cursor includes Dy(tmhd)₃, where tmhd=2,2,6,6-tetramethyl-3,5-heptanedionate.

A non-limiting example of an Er precursor includes Er(tmhd)₃, where tmhd=2,2,6,6-tetramethyl-3,5-heptanedionate.

Non-limiting examples of an Y precursor include yttrium tris(N,N′-diisopropylacetamidinate) (“Y(iPr₂amd)₃”), (CpCH₃)₃Y were Cp=cyclopentadienyl, tris (2,2,6,6-tetramethyl-3,5-heptanedionate) yttrium (“Y(tmhd)₃”), to name a few.

Non-limiting examples of a Sc precursor include tris (2,2,6,6-tetramethyl-3,5-heptanedionate) Scandium (Sc(tmhd)₃), Sc(MeCp)₃, Sc(MeCp)₂(Me₂pz) (1, MeCp=methylcyclopentadienyl, Me₂pz=3, 5-dimethylpyrazolate).

A non-limiting example of an Al precursor includes Al(CH₃)₃ (“TMA”).

Non-limiting examples of a Hf precursor include Hf[N(CH₃)(C₂H₅)]₄ (“TEMAH”) and Hf[N(CH₃)₂]₄.

Non-limiting examples of a Zr precursor include Zr[N(CH₃)(C₂H₅)]₄ (“TEMAZ”), Zr[N(CH₃)(C₂H₅)]₄(“TEMAZ”), and Zr[N(CH₃)₂]₄, and Zr[N(CH₃)₂]₄.

In various embodiments, the deposition temperature of the first and second metal oxides 312A, 312B (FIG. 3B) can depend on the application. For example, for various applications described herein including forming a capacitor for a random access memory (RAM) such as ferroelectric RAM (FeRAM) or dynamic RAM (DRAM), as well as a gate dielectric of a field effect transistor (FET) such as ferroelectric FET (FeFET), the metal oxides may be formed at a substrate temperature of 150 °C-200 °, 200 °C-250 °C, 250 °C-300 °C, 300 °C-350 °C, 350 °C-390 °C, 350 °C-400 °C, or a temperature in a range defined by any of these values, according to embodiments.

### Metal Oxide Formation of Metal Oxide by Cyclic Deposition Using Back-to-Back Exposures to Water Followed by Ozone

As described above, a first inventive aspect that employs water and ozone in an orderly combination of steps as part of cyclic deposition methods includes sequential deposition of sublayers, where the first sublayer is formed by employing water (H₂O) as the oxidizing precursor in first cycles, and the second sublayer is formed by employing ozone (O₃) as the oxidizing precursor in second cycles. A second inventive aspect that employs H₂O and O₃ in an orderly combination of steps includes exposing the substrate to both H₂O and O₃ as part of the same cycle with one or more metal precursors. In the alternative inventive aspect, instead of forming sublayers, each cycle of a cyclic deposition process includes exposures to both water and ozone. The resulting oxide thin films can synergistically reap the benefits of both water and ozone as oxidizing precursors.

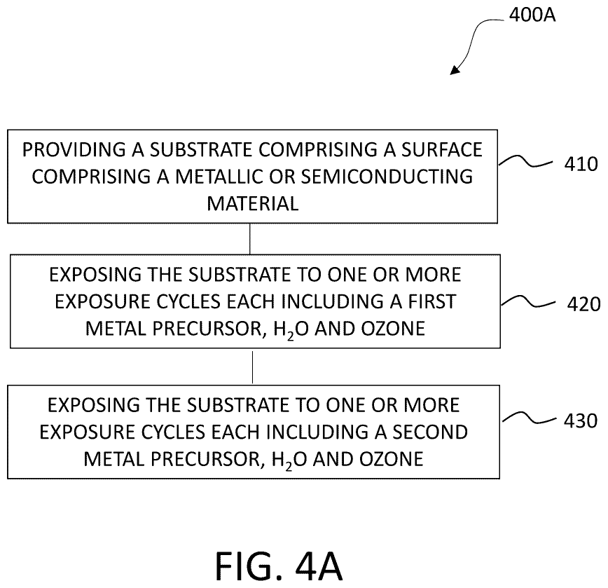

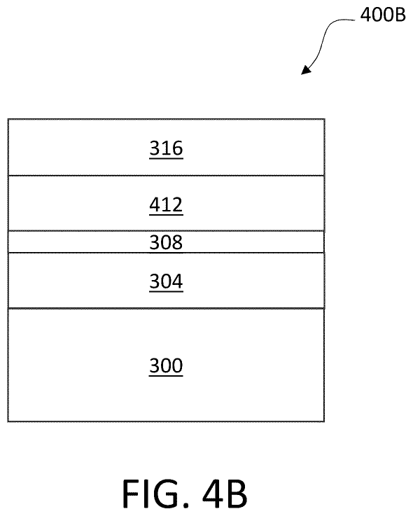

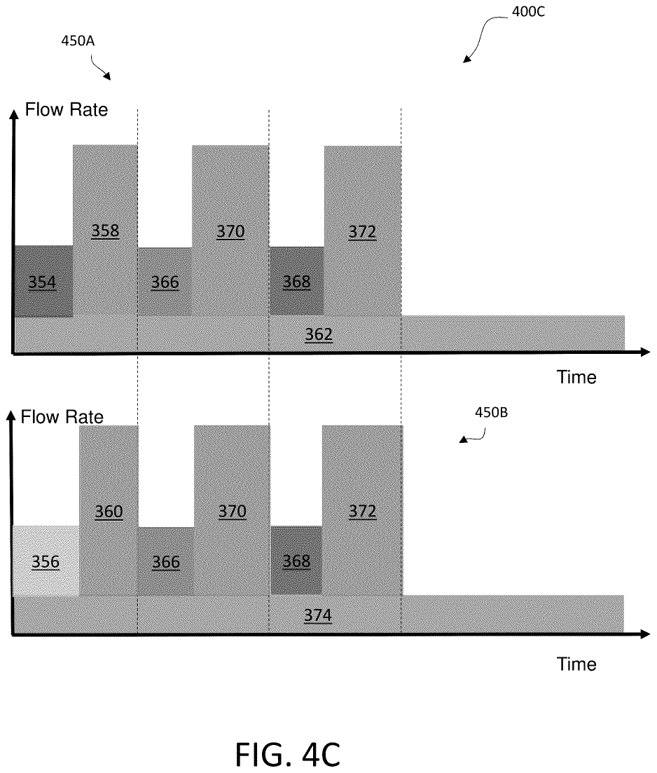

FIG. 4A is a flow chart illustrating a method 400A of forming a metal oxide by cyclic deposition, according to embodiments. FIG. 4B shows a device stack 400B including the metal oxide formed by the method illustrated in FIG. 4A. FIG. 4C schematically illustrates an example precursor delivery sequence 400C for forming the metal oxide according to the method illustrated in FIG. 4A. In the following, the method 400A (FIG. 4A) is described in conjunction with the device stack 400B and the precursor delivery sequence 400C.

The method 400A includes providing 410 a substrate comprising a surface comprising a metallic or semiconducting material. The method 400A additionally includes exposing 420 the substrate to one or more exposure cycles each including a first metal (M1) precursor, H₂O and ozone. The method 400A further includes exposing 430 the substrate to one or more exposure cycles each including a second metal (M2) precursor and H₂O and ozone.

Various aspects of the first inventive aspect described above with respect to FIGS. 3A-3C can equally apply to the second inventive aspect described herein, and the details of overlapping inventive aspects will be omitted herein for brevity, unless described differently or additionally herein.

Referring to FIG. 4B, the resulting device stack 400B has the same corresponding layers including a metal oxide 412 be formed over a substrate 300 having formed thereon a bottom electrode 304. Similarly, a top electrode 316 can be formed over the metal oxide 412, and an interfacial layer 308 may be present. However, unlike the metal oxide 312 described above with respect to FIG. 3B, in which the metal oxide 312 includes two sublayers 312A, 312B formed using H₂O and O₃ as oxidizing precursors, respectively, the metal oxide 412 is formed without such distinguishable sublayers based on the oxidizing precursor. As such, different regions or portions of the metal oxide 412 may be substantially homogeneous and not be substantially distinguishable, e.g., based on oxygen content (or lower oxygen vacancy concentration) and/or OH content.

FIG. 4C schematically illustrates an example precursor delivery sequence for forming the metal oxide illustrated in FIG. 4B using the method illustrated in FIG. 4A, according to embodiments. Referring to FIG. 4C, a precursor delivery sequence for the cyclic deposition or ALD according to embodiments comprises one or more first cycles 450A and one or more second cycles 450B. The first cycle 450A can correspond to exposing 420 (FIG. 4A) the substrate to one or more exposure cycles each including a first metal (M1) precursor, H₂O and ozone. In the illustrated embodiment in FIG. 4C, each of the first cycles 450A includes an exposure 354 of the substrate to the M1 precursor, an exposure 366 to water (H₂O), and an exposure 368 to ozone (O₃). In addition, each of the second cycles 450B includes an exposure 356 of the substrate to a second metal (M2) precursor, an exposure 366 to H₂O, and an exposure 368 to O₃. Without limitation, referring back to FIG. 2, in one implementation and without limitation, the introduction of H₂O for exposure 366 to H₂O may be performed through a first ALD precursor delivery line, and the introduction of ozone for exposure 368 to O₃ may be performed through a second ALD precursor delivery line to suppress the interaction between surface adsorbed H₂O and ozone.

In the illustrated embodiment, the first and second metal precursors may be different. By way of example, when the metal oxide 412 (FIG. 4B) comprises a hafnium zirconium oxide (HZO), exposure 354 to the first metal precursor may be an exposure to a Hf precursor and the exposure 356 to the second metal precursor may be an exposure to a Zr precursor. However, embodiments are not so limited and in some other embodiments, the first and second metal precursors may be the same within one or both of first and second cycles 450A, 450B.

In a similar manner as described above with respect to FIG. 3C, one or both of the first and second cycles 450A, 450B can include a respective continuous purge 362, 374. In addition, the first and second cycles 450A, 450B can include respective rapid purges 358, 360, 370, 372 following exposures 354, 356, 366, 368 to the first metal precursor, the second metal precursor, H₂O and ozone, respectively.

Thus, according to various embodiments described herein with respect to FIGS. 4A-4C, in the method 400A (FIG. 4A), exposing 420 the substrate to one or more exposure cycles can include exposing the substrate to N number (1 or greater) of first cycles 450A (FIG. 4C) each including exposing 420 the substrate to one or more exposure cycles each including a first metal precursor, H₂O and ozone. In addition, in the method 400A, exposing 430 to a plurality of exposure cycles can include exposing the substrate to M number (1 or greater) of second cycles 450B (FIG. 4C) each including one or more exposure cycles each including a second metal precursor, H₂O and ozone.

### Hf-Based Oxide Deposition by Sequential Cyclic Depositions of Sublayers Using Water Followed by Ozone

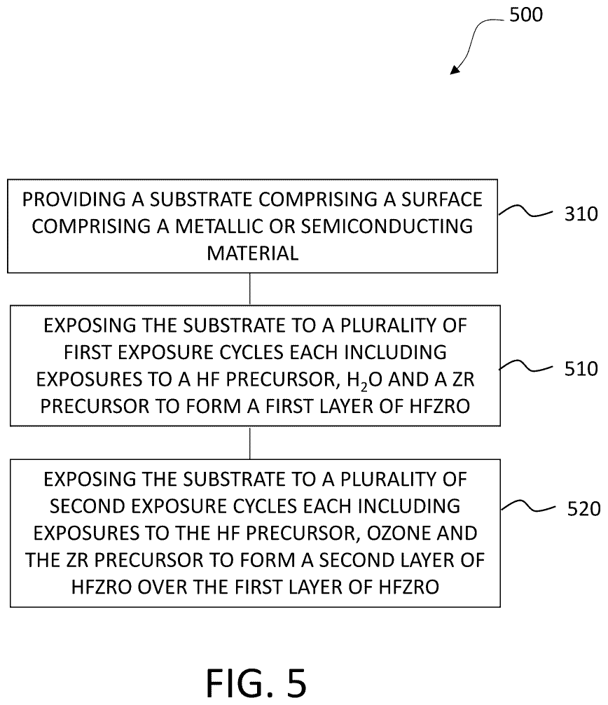

Hf-based oxides, including HfO (e.g., HfO₂) and HfZrO (or HZO, e.g., HfZrO₂), find many applications, including high k dielectrics for field effect transistors as well as ferroelectric and resistive switching memory devices. Hf-based oxide have several attractive attributes, including relatively low process temperature, complementary metal-oxide-semiconductor (CMOS) process compatibility, and availability in different phases including the amorphous phase. However, the presence of defects can greatly affect the device performance, and therefore the ability to control or engineer the defects can limit the device performance, depending on the circumstances. Defects in Hf-based oxides such as HZO can be affected by a variety of factors, including the type of electrodes, growth and/or post growth annealing temperature, and precursor type and exposure conditions. Without being bound to any theory, oxygen vacancy (Vₒ) has been attributed to various physical and electrical properties and device performance in devices incorporating Hf-based oxides. In particular, Vₒ is believed to be related to the polymorphism of Hf-based oxides and the resulting ferroelectric properties. Moreover, the switching speed, endurance and variability of ferroelectric memories are believed to be correlated to the Vₒ concentration and redistribution. Further, when HZO films are directly formed on some surfaces such as Si, an interfacial layer such as SiOₓ can be formed, which can cause charge trapping, increased leakage current, and increased external switching voltage due to the lower dielectric constant of the interfacial layer and a strong depolarization field. By employing both water and ozone according to various methods described herein, e.g., the embodiment analogous to that described above with respect to FIGS. 3A-3C, the inventors have discovered that bulk defects and/or interfacial layers can be particularly effectively controlled in formation of Hf-based oxides, e.g., HZO. The first embodiment, illustrated with respect to FIG. 5, is analogous to the method described with respect to FIGS. 3A-3C, and is described herein conjunction therewith.

As disclosed herein, unless specified otherwise, HfO and HfZrO generally refer to hafnium oxides and hafnium zirconium oxides including stoichiometric and substoichiometric compositions. For example, HfO and HfZrO may refer to stoichiometric and substoichiometric HfOx and HfZrOx, where x can be 1.0-1.2, 1.2-1.4, 1.4-1.6, 1.6-1.8, 1.8-2.0, or a value in a range defined by any of these values. Further, HfZrO may be Hf-rich or Zr-rich, and the ratio of Hf and Zr concentrations may be lower than 0.7, 0.6, 0.5, 0.4, 0.3, or a value in a range defined by any of these values.

Referring to FIG. 5, a method 500 of forming a ferroelectric layer comprising Hf and Zr for a semiconductor device according to the first embodiment comprises providing a substrate comprising a surface comprising a metallic or semiconducting material, in a similar manner as described above with respect to FIGS. 3A-3C. The method 500 additionally comprises exposing 510 the substrate to a plurality of first exposure cycles each including exposures to a Hf precursor, H₂O and a Zr precursor to form a first layer of HZO. The method 500 additionally comprises exposing 520 the substrate to a plurality of second exposure cycles each including exposures to the Hf precursor, ozone and the Zr precursor to form a second layer of HZO over the first layer of HZO. The first and second layers of HZO are formed in situ in the same reactor chamber. The method 500 can be a particular implementation of the method 300A illustrated in FIG. 3A, and the resulting device stack can be represented by the device stack 300B (FIG. 3B), in which the first and second oxide layers 312A, 312B are formed by exposing 510 the substrate 300 to the plurality of first exposure cycles each including exposures to a Hf precursor, H₂O and a Zr precursor, and exposing 520 the substrate 300 to the plurality of second exposure cycles each including exposures to the Hf precursor, O₃ and the Zr precursor. The precursor delivery sequence for the method 500 can be represented by the precursor delivery sequence illustrated in FIG. 3C including a plurality of first cycles 350A and a plurality of second cycles 350B. Referring back to FIG. 3A, the first cycles 350A can correspond to exposing 320 (FIG. 3A) the substrate to a plurality of exposure cycles each including one or more metal precursors to form the first metal oxide 312A (FIG. 3A). As applied to the illustrated embodiment in FIG. 5, each of the first cycles 350A in turn includes an exposure of the substrate to sequential exposures to the Hf precursor, followed by H₂O, followed by the Zr precursor, followed by H₂O. Similarly, the second cycles 350B can correspond to exposing 330 (FIG. 3A) the substrate to a plurality of exposure cycles each including one or more metal precursors to form the second metal oxide 312B (FIG. 3B). As applied to the illustrated embodiment in FIG. 5, each of the second cycles 350B in turn includes sequential exposures to the Hf precursor, followed by the O₃, followed by the Zr precursor, followed by O₃.

The inventors have discovered that exposures to the precursors during the first and second exposure cycles 350A, 350B, can be controlled to optimize bulk oxygen vacancy and interstitial defects, as well as suppressing interlayer formation. Thus controlled defects can in turn improve leakage current, breakdown voltage, remnant polarization, coercive electric field as well as the phase of the HfZrO. Without being bound to any theory, the ferroelectric orthorhombic phase may be promoted in favor of non-ferroelectric monoclinic phase by optimizing the ozone exposure time during atomic layer deposition.

In particular, the methods according to embodiments can control the profile of Vₒ within the HfZrO film. Without being bound to any theory, the presence of Vo induces an imperfect bonding state in crystals with three-dimensional periodic arrays of atoms, ions, molecules, or their groups. The presence of Vₒ strongly influences the physical/chemical properties of metal oxides. Electrostatically, the Vₒ can form electron trap levels in the forbidden bandgap. For resistive memory applications, the Vₒ profile can aid in filament formation by accumulated Vₒ. For ferroelectric HfZrO films, particular Vₒ concentration profile can promote the dominance of the ferroelectric orthorhombic phase.

Still referring to FIG. 5, in the method 500, exposing 510 the substrate to a plurality of first exposure cycles can include exposing the substrate to N number (1 or greater) of first exposure cycles 350A (FIG. 3C) each including exposures to a Hf precursor, H₂O and a Zr precursor to form a first layer of HfZrO (e.g., 312A of FIG. 3B).

According to embodiments, in reference to FIG. 3C, the precursor pulse times for each exposure 354 to the Hf precursor and each exposure 356 to the Zr precursor can be between 0.1-10 sec., 0.5-5 sec., 1-3 sec., or a value in a range defined by any of these values; pulse times for the rapid purges 358, 360 following the precursor exposures can be between 0.1-100 sec., 0.5-50 sec., 1-10 sec., or a value in a range defined by any of these values; the pulse times for the each exposure 366 to H₂O can be between 0.1-15 sec., 0.5-10 sec., 1-5 sec., or a value in a range defined by any of these values; and pulse times for the rapid purge 370 following the H₂O exposures can be between 0.1-100 sec., 0.5-50 sec., 5-20 sec., or a value in a range defined by any of these values.

Still referring to FIG. 5, in the method 500, exposing 520 the substrate to of second exposure cycles can include exposing the substrate M number (1 or greater) of second exposure cycles 350B (FIG. 3C) each including alternating exposures to the Hf precursor, O₃ and the Zr precursor to form a second layer of HfZrO over the first layer of HfZrO (e.g., 312B of FIG. 3B).

According to embodiments, in reference to FIG. 3C, the precursor pulse times for each exposure 354 to the Hf precursor and each exposure 356 to the Zr precursor can be between 0.1-10 sec., 0.5-5 sec., 1-3 sec., or a value in a range defined by any of these values; pulse times for the rapid purges 358, 360 following the precursor exposures can be between 0.1-100 sec., 0.5-50 sec., 1-10 sec., or a value in a range defined by any of these values; the pulse times for the each exposure 368 to O₃ can be between 0.1-20 sec., 0.5-15 sec., 1-10 sec., or a value in a range defined by any of these values; and pulse times for the rapid purge 372 following the O₃ exposures can be between 0.1-100 sec., 0.5-50 sec., 5-30 sec., or a value in a range defined by any of these values.

Still referring to FIG. 5, according to embodiments, by controlling exposing 510 the substrate to N first exposure cycles 350A (FIG. 3C) to form the first oxide 312A (FIG. 3B) comprising HfZrO formed using H2O and exposing 520 to M second exposure cycles 350B (FIG. 3C) to form the second oxide 312B (FIG. 3B) comprising HfZrO using O₃, the resulting metal oxide 312 comprising HfZrO can be optimized for ferroelectric applications. The inventors have discovered that N can be selected to be less than 100, 80, 60, 40, 20, 10, 5, or a value in a range defined by any of these values, for forming the first oxide layer 312A comprising HfZrO using H₂O to suppress interlayer formation. Subsequently, M can be selected to be a suitable number to form the second oxide layer 312B comprising HfZrO using O₃, thereby forming the overall metal oxide 312 comprising HfZrO having a target thickness with suppressed interlayer formation and controlled vacancy concentration and profile. For example, M can be 30-50 to form a ferroelectric HZO having a thickness of 8-12 nm, which has been down to have high remnant polarization.

### Hf-Based Oxide Deposition by Cyclic Deposition Using Back-to-Back Exposures to Water Followed by Ozone

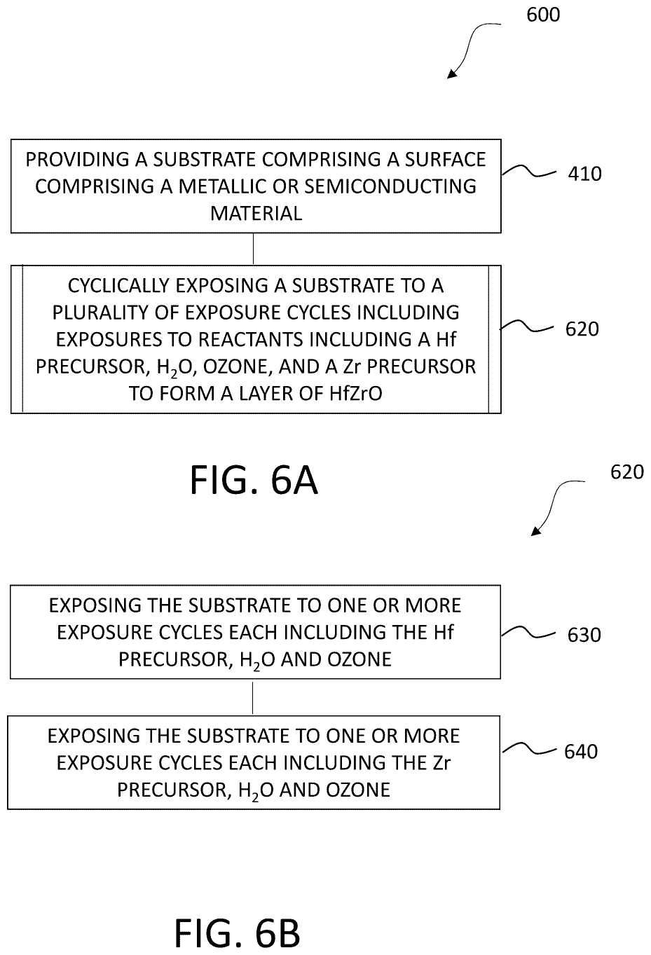

By employing both water and ozone according to a second embodiment analogous to that described above with respect to FIGS. 4A-4C, the inventors have discovered that bulk defects and/or interfacial layers can be particularly effectively controlled in the resulting Hf-based oxides, e.g., HZO. The second embodiment analogous to the method described with respect to FIGS. 4A-4C is described herein with respect to FIGS. 6A and 6B.

Referring to FIG. 6A, a method 600 of forming a ferroelectric layer comprising Hf and Zr for a semiconductor device according to the second embodiment comprises providing 410 a substrate comprising a surface comprising a metallic or semiconductor material. The method 600 additionally includes cyclically exposing 620 a substrate to a plurality of exposure cycles including exposures to reactants including a Hf precursor, H₂O, ozone, and a Zr precursor to form a layer of HfZrO (HZO), wherein at least one of the exposure cycles includes exposures to both H₂O and ozone. The method 600 can be a particular implementation of the method 400A illustrated in FIG. 4A where M1 and M2 are Hf and Zr, respectively, such that the resulting layer of HZO layer can be represented by the device stack 400B (FIG. 4B), in which the oxide layers 412 is formed by exposing 620 the substrate 300 to a one or more exposure cycles each including a Hf precursor, H₂O and O₃, and to one or more exposure cycles each including a Zr precursor, H₂O and ozone. The precursor delivery sequence for the method 600 can be performed using the precursor delivery sequence illustrated in FIG. 4C including a plurality of first cycles 450A and a plurality of second cycles 450B. Referring back to FIG. 4A, as applied to the method 600, the first cycles 450A can correspond to exposing 420 (FIG. 4A) the substrate to one or more exposure cycles each including a Hf precursor, H₂O and O₃, and the second cycles 450B can correspond to exposing 430 (FIG. 4A) the substrate to one or more exposure cycles each including a Zr precursor, H₂O and O₃. This implementation is illustrated in FIG. 6B.

Referring to FIG. 6B, cyclically exposing 620 the substrate to the plurality of exposure cycles includes exposing 630 the substrate to one or more exposure cycles each including a Hf precursor, H₂O and O₃, and further includes exposing 640 the substrate to one or more exposure cycles each including a Zr precursor, H₂O and O₃. Thus, cyclically exposing 620 illustrated with respect to FIG. 6A can represent a super cycle including exposing 630 and 640 illustrated with respect to FIG. 6B, which includes first and second cycles 450A, 450B, where M1 and M2 are Hf and Zr, respectively.

The inventors have discovered that exposing 630 the substrate to one or more exposure cycles, each including exposures to a Hf precursor, H₂O and O₃, and exposing 640 the substrate to one or more exposure cycles, each including exposures to a Zr precursor, H₂O and O₃, can be controlled to optimize bulk oxygen vacancy and interstitial defect concentration and/or profile, as well as to suppress interlayer formation, in a similar manner as described above with respect to FIG. 5. Thus controlled defects can in turn improve leakage current, breakdown voltage, remnant polarization, coercive electric field as well as the phase of the oxide, among other properties. Without being bound to any theory, the ferroelectric orthorhombic phase may be promoted in favor of non-ferroelectric monoclinic phase by optimizing the ozone exposure time according to the method 600.

According to embodiments, in reference to FIG. 4C, the precursor pulse times for each exposure 354 to the Hf precursor and each exposure 356 to the Zr precursor can be between 0.1-10 sec., 0.5-5 sec., 1-3 sec., or a value in a range defined by any of these values; pulse times for the rapid purges 358, 360 following the precursor exposures can be between 0.1-100 sec., 0.5-50 sec., 1-10 sec., or a value in a range defined by any of these values; the pulse times for the each exposure 366 to H₂O can be between 0.1-15 sec., 0.5-10 sec., 1-5 sec., or a value in a range defined by any of these values; pulse times for the rapid purge 370 following the H₂O exposures can be between 0.1-100 sec., 0.5-50 sec., 5-20 sec., or a value in a range defined by any of these values; the pulse times for the each exposure 368 to ozone can be between 0.1-20 sec., 0.5-15 sec., 1-10 sec., or a value in a range defined by any of these values; and pulse times for the rapid purge 372 following the ozone exposures can be between 0.1-100 sec., 0.5-50 sec., 5-30 sec., or a value in a range defined by any of these values.

Still referring to FIGS. 6A and 6B, according to embodiments, by controlling the number of exposures in cyclically exposing 620 the substrate to a plurality of exposure cycles, the resulting metal oxide 412 (FIG. 4B) can be optimized for ferroelectric applications. For example, exposing 630 the substrate to one or more exposure cycles each including a Hf precursor, H₂O and O₃ can be performed M number cycles, and exposing 640 the substrate to one or more exposure cycles each including a Zr precursor, H₂O and O₃ can be performed N number of cycles. Each of M and N can be selected to be less than 100, 80, 60, 40, 20, 10, 5 or 1 or a value in a range between any of these values. The sum of M first cycles and N second cycles can in turn be performed L number of times of supercycles to form the HfZrO having a target thickness. For example, for M=N=1, the inventors have discovered that the number L of supercycles can be 40-60 to form a ferroelectric HZO having a thickness of 8-12 nm, which has been shown to have high remnant polarization.

### Experimental Examples

According to various embodiments, the inventors have discovered certain parameters to be critical in yielding high remnant polarization in ferroelectric oxides including mixed transition oxides such as HfZrO. In particular, the inventors have discovered that Hf:Zr dose ratio, the HfZrO thickness, O₃ pulse time and O₃ concentration during O₃ exposures and H₂O pulse time and H₂O concentration during O₃ exposures, among other control parameters, can be critical for achieving good ferroelectric properties including remnant polarization and switching voltage. Without being bound to any theory, the observed criticality may be associated with generation of particular concentration and/or profile of oxygen vacancies. The oxygen vacancy characteristics can in turn be correlated with the stability of the orthorhombic phase, which has been associated with the observed ferroelectric phenomena.

First, in the method 500 (FIG. 5), in one or both of exposing 510 and exposing 520, a ratio of the Hf dose to the Zr dose can be 70:30, 65:35, 60:40, 55:45, 50:50 or a ratio in range defined by any of these ratios, for instance 58:42. Similarly, in the method 600 (FIGS. 6A and 6B), in one or both of exposing 630 and exposing 640, a ratio of the Hf dose to the Zr dose can be 70:30, 65:35, 60:40, 55:45, 50:50 or a ratio in range defined by any of these ratios, for instance 58:42.

As described herein, the dose refers to the time-accumulated sum of the number of molecular contact events per area of the reactant molecules on a substrate surface. The dose can be proportional to the partial pressure of the reactant and the exposure time. Thus, a dose ratio can be achieved by achieving a corresponding ratio of exposure times of Hf and Zr precursors for a fixed precursor partial pressure in the chamber, or alternatively by achieving a corresponding ratio of precursor partial pressures of Hf and Zr precursors for a fixed exposure time, or a combination to achieve a corresponding ratio of the products of exposure times and partial pressures.

Second, in both the method 500 (FIG. 5) and the method 600 (FIGS. 6A, 6B), the total thickness of the HfZrO film can be 7-8 nm, 8-9 nm, 9-10 nm, 10-11 nm, 11-12 nm, 12-13 nm or a value in a range defined by any of these values, e.g., about 10 nm.

Third, in both the method 500 (FIG. 5) and the method 600 (FIGS. 6A, 6B), the duration of ozone exposures (e.g., exposures 368 in FIG. 3C and FIG. 4C) can be 2-4 sec., 4-6 sec., 6-8 sec., 8-10 sec., 10-12 sec., 12-14 sec., 14-16 sec., 16-18 sec., or a value in a range defined by any of these values, for instance between about 3 sec. and 18 sec.

Fourth, in both the method 500 (FIG. 5) and the method 600 (FIGS. 6A, 6B), the molar concentration of ozone during ozone exposures (e.g., exposures 368 in FIG. 3C and FIG. 4C) can be 15-17%, 17-19%, 19-21%, 21-23%, 23-25%, 25-27%, or a value in a range defined by any of these values, for instance about 21%. These concentrations can be converted to weight per volume at a given condition. For example, under STP conditions, 100 g O₃/m₃ can be about 7.8% in air and about 7% in oxygen. The volume percentages can be on the basis of the total volume, which additionally can include other gases such as an inert gas of the continuous purge. The volume percentage can be inferred, e.g., based on the flow ratios of ozone versus the inert gas.

The inventors have experimentally produced various HfZrO films according to various embodiments as described above for experimental validation. In particular, for demonstrative purposes, HfZrO films were deposited on a Si substrate using TEMAH and TEMAZ according to embodiments described above with respect to FIG. 5 and FIGS. 6A and 6B at temperatures of 150 °C to 350 °C. The HfZrO films were deposited using QXP-8300® ALD system by Eugenus, Inc., based in San Jose, California.

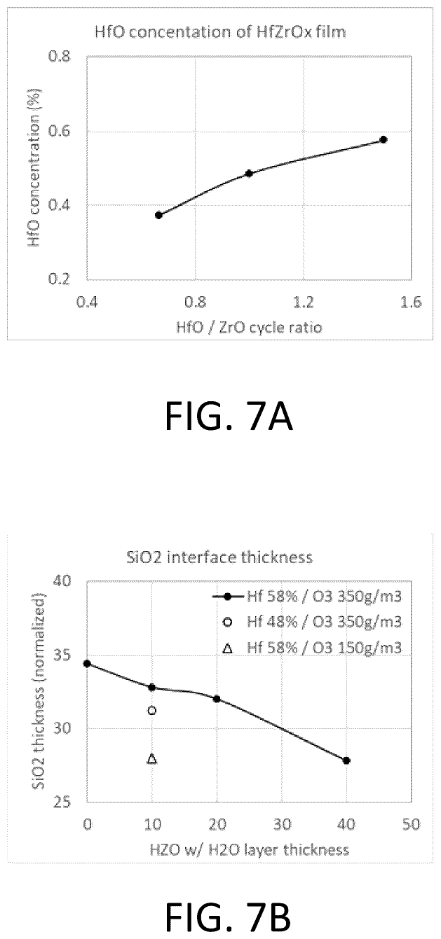

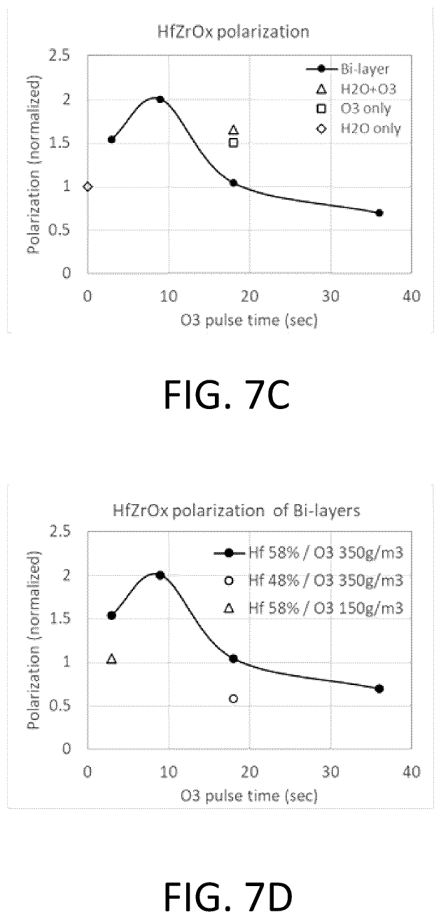

FIG. 7A illustrates experimentally measured HfO concentrations (in mol %) of the HfZrO films as a function of the ratio of the HfO cycles to the ZrO cycles (corresponding to the ratio of doses of HfO and ZrO)), as confirmed by X-ray photoelectron spectroscopy.

FIG. 7B illustrates the interfacial SiO₂ thickness as a function of the thickness of the first layer of HZO resulting from exposing 510 (FIG. 5) the substrate to a plurality of first exposure cycles each including exposures to a Hf precursor, H₂O and a Zr precursor. The thickness values were determined using time-of-flight secondary ion mass spectrometry (TOF-SIMS) by measuring peak area of SiO₂ at the interface between Si substrate and the HfZrO films. The results illustrate that higher thickness of the first layer of HfZrO grown using H₂O as the oxidant clearly reduces interface oxidation. The results also show that lower O₃ concentration (as measured in g/m³) and lower HfO concentration (as measured in molar % of HfO) also resulted in lower interfacial SiO₂ thickness. As described above, the interfacial SiO₂ can be detrimental to electrical and/or ferroelectric properties, e.g., can increase the leakage current. In addition, without being bound by any theory, the presence of SiO₂ interfacial layer can disrupt seed formation for high degree of crystallization of HfZrO in the orthorhombic crystal structure associated with high remnant polarization.

FIG. 7C is a graph illustrating experimentally measured remnant polarization (normalized) as a function of various HfZrO thin films deposited under various oxidant exposure conditions, according to embodiments. The oxidant conditions tested included using H₂O only (“H2O only”), using O₃ only (“O3 only”), and both H₂O and O₃ (“H2O+O3”) according to various embodiments. The HfZrO formed using H₂O only was formed according to the exposing 510 (FIG. 5) the substrate in the method 500 of forming the first layer of the HfZrO using H₂O. The HfZrO formed using O₃ only was formed according to the exposing 520 (FIG. 5) the substrate in the method 500 of forming the second layer of the HfZrO using O₃. The HfZrO formed using both H₂O and O₃ was formed according to the method described above with respect to FIGS. 6A and 6B. The oxidant conditions tested further included HfZrO films formed as bilayers according to the method described above with respect to FIG. 5 (“Bi-layer”). For the bilayer samples measured, the lower layer deposited using H₂O only was about 1 nm and the upper layer deposited using O₃ was about 5.5 nm. The O₃ concentration was about 350 g/m³ for all O₃ exposures. The maximum polarization measured by P-V analysis showed about 40 μC/cm² for 2 Pr by ±2V double sweep at 250 MHz.

As shown, for the HfZrO films formed as bilayers according to the method described above with respect to FIG. 5, the highest level of measured remnant polarization was observed for O₃ exposure time of about 9 sec. As illustrated, the measured polarization shows an unexpected peak at 9 sec., or between 3 sec. and 18 sec. of exposure times. The HfZrO film formed as a bilayer with 9 sec. of exposure time showed the highest level of polarization than any other tested conditions. The results illustrate that there is a critical optimum range of exposure to O₃ that is associated with high polarization. That is, too low or too high of an O₃ dose can result in lower polarization. Without being bound to any theory, this observation can imply that high polarization may be associated with an optimum concentration of oxygen vacancies or crystal imperfections.

Still referring to FIG. 7C, HfZrO films formed using H₂O only as the oxidant (“H2O only”) resulted in relatively low remnant polarization among the measured films. While not shown, these films demonstrated relatively low interfacial SiO₂ and lowest leakage current, implying that higher leakage current may be associated with higher interfacial SiO₂ thickness. While HfZrO films formed using O₃ only as the oxidant (“O3 only”) resulted in an improvement over the HfZrO films formed using H₂O only, these films resulted in relatively high interfacial SiO₂. On the other hand, HfZrO films formed using both H₂O and O3 as oxidants (“H2O+O3”) showed good balance with relatively high remnant polarization and reduced interfacial SiO₂ thickness. Without being bound to any theory, the balanced results may indicate that some of O₃ reacted with H₂O and decomposed to O₂, thereby lowering the available O₃ concentration, leading to higher oxygen vacancy concentration relative to HfZrO films formed using O₃ only as the oxidant.

FIG. 7D is a graph illustrating experimentally measured remnant polarization as a function of various HfZrO thin films deposited under various oxidant exposure conditions, according to embodiments. The measured HfZrO films were all formed as bilayers according to the method described above with respect to FIG. 5 at different overall HfO concentrations and different O₃ exposure conditions for the upper layers of HfZrO films. The results indicate that, as discussed above, for the HfZrO films formed as bilayers with 58% molar concentration of HfO, the measured remnant polarization demonstrated a peak for O₃ exposure time of 9 sec. For the same O₃ exposure times, both lower HfO concentration and lower O₃ concentration resulted in lower remnant polarization levels. In short, from a ferroelectric device application perspective, a HfO-rich composition, using both H₂O and O₃ as oxidants, and an optimized O₃ dose have been shown to be effective at improving the remnant polarization.

### Device Applications of Ferroelectric Thin Films

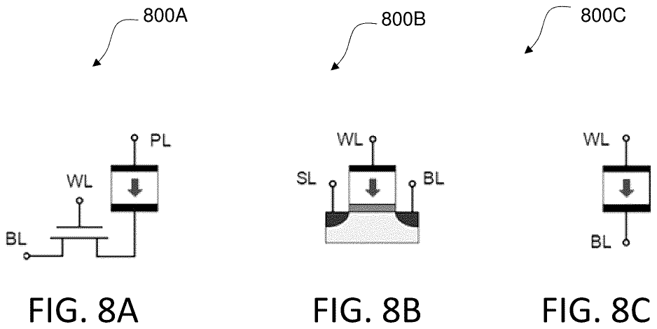

FIGS. 8A-8C illustrate example device applications of ferroelectric thin films, e.g., Hf-based thin films, according to embodiments. Each of the devices depicted in FIGS. 8A-8C can have a device stack similar to the device stack 300B depicted in FIG. 3B or the device stack 400B depicted in FIG. 4B, each including a ferroelectric oxide disposed between an upper and lower electrodes. The arrow represents a remnant polarization in the ferroelectric oxide.

FIG. 8A schematically illustrates a one transistor-one capacitor (1T1C) ferroelectric random access memory (FeRAM) device 800A. The FeRAM device 800A includes a capacitor connected to a drain of a transistor, and the source and drain of the transistor connect to a bitline and a wordline, respectively. The ferroelectric oxide disposed between the upper and lower electrodes form a ferroelectric capacitor for storing information. The change in capacitance caused by the change in polarization state of the ferroelectric oxide is detected as a change in the memory state. FIG. 8B schematically illustrates a one transistor (1T) ferroelectric field effect transistor (FeFET) device 800B. The FeFET device 800B is a transistor device, where the gate and drain of the transistor connect to a wordline and a bitline, respectively. The ferroelectric oxide disposed between the gate of the transistor and the channel stores information. The change in the ferroelectric state causes a change in threshold voltage of the transistor, which can be detected as a change in the memory state. FIG. 8C illustrates a ferroelectric tunnel junction (FTJ) device 800C. The FTJ device is a two-terminal device, in which the ferroelectric oxide is disposed between a wordline, which is connected to, or can serve as, the upper electrode, and a bitline, which is connected to, or can serve as, the lower electrode, to form a ferroelectric tunnel junction. The change in the ferroelectric state causes a change in tunnel current or voltage, which can be detected as a change in the memory state.

It will be appreciated that, while example devices illustrated in FIGS. 8A-8C are integrated with metal oxides formed using water and ozone according to embodiments that have ferroelectric properties, embodiments are not so limited, and the integrated metal oxides can be integrated for properties other than or in addition to the ferroelectric properties. For example, the capacitor illustrated in FIG. 8A can represent a DRAM capacitor having a high aspect ratio, and the integrated metal oxide can be a high k dielectric formed using any of the precursors disclosed above. In addition, the transistor illustrated in FIG. 8B can represent a MOS transistor, and the integrated metal oxide can be a high k dielectric formed using any of the precursors disclosed above.

Each of the devices 800A, 800B and 800C stores data in a polarization state in the ferroelectric (FE) layer similar to those described above with respect to FIGS. 3B and 4B. A write operation may be performed by applying an electrical field. Without being bound to any theory, the switching in FE layers may be nucleation-limited and may exhibit a time-voltage trade-off for polarization and polarization reversal. That is, higher voltage may lead to faster switching and vice versa. For switching of Hf-based (e.g., HZO) films formed according to embodiments, switching of the order of nanoseconds are possible. In each of the devices 800A, 800B and 800C illustrated in FIGS. 8A-8C, for ferroelectric layer thicknesses of 5-10 nm, a switching voltage can be in the range of 1-4 V or less. While programming is broadly similar for the devices illustrated in FIGS. 8A-8C, read operations are more distinct.

In the 1T1C FeRAM device 800A (FIG. 8A), during a destructive readout, the switched polarization charge is transferred via a select transistor to a bit line. Similar as in DRAM, a sense amplifier determines the stored logic state. The readout cycle is completed by restoring the information. In the 1T FeFET device 800B (FIG. 8B), the polarization charge of the ferroelectric gate oxide material controls the threshold voltage of the transistor and thus its channel conductivity. Hence, making use of the transistors internal gain, a non-destructive readout operation can be achieved by sensing the drain-source-current, while maintaining nonvolatile data stored in the capacitors. In the FTJ device 800C (FIG. 8C), two metal electrodes are separated by a thin ferroelectric layer. The electrical resistance of the device can be controlled by switching the polarization of the ferroelectric material. The FTJ device 800C serves as a non-volatile memory element due to the ability to store information based on the polarization state. The switching is achieved by applying an electric field across the junction, leading to resistance changes depending on the polarization direction.

### Additional Examples

1. A method of forming a ferroelectric layer comprising Hf and Zr for a semiconductor device, the method comprising:
exposing a substrate to a plurality of first exposure cycles each including exposures to a Hf precursor, H₂O and a Zr precursor to form a first layer of HfZrO; and
exposing the substrate to a plurality of second exposure cycles each including exposures to the Hf precursor, ozone and the Zr precursor to form a second layer of HfZrO over the first layer of HfZrO,
wherein the first and second layers of HfZrO are formed in situ in a same reactor chamber.

2. The method of Example 1, wherein each of the first exposure cycles comprises sequential exposures to the Hf precursor, followed by H₂O, followed by the Zr precursor, followed by H₂O.

3. The method of Example 2, wherein each of the second exposure cycles comprises sequential exposures to the Hf precursor, followed by the ozone, followed by the Zr precursor, followed by ozone.

4. The method of Example 3, wherein each exposure to ozone comprises an exposure to a mixture of ozone and water, wherein a ratio of ozone to water by volume substantially exceeds 4%.

5. The method of Example 2, wherein a ratio of a number (M) of the second exposure cycles to a number (N) of the first exposure cycles exceeds 3.

6. The method of Example 1, wherein the first layer of HfZrO is formed directly on a Si surface or a TiN surface.

7. The method of Example 1, wherein the method comprises a thermal deposition that forms the ferroelectric layer without aid of a plasma.

8. The method of Example 7, wherein the method is performed at a substrate temperature of 150-350 °C.

9. The method of Example 1, wherein each of the first and second layers of HfZrO is oxygen deficient and expressed by a chemical formula HfₓZr₁₋ₓO_{2-y}, wherein each of x and y is greater than zero.

10. The method of Example 9, wherein y is greater in the first layer of HfZrO relative to the second layer of HfZrO.

11. A method of forming a ferroelectric layer comprising Hf and Zr for a semiconductor device, the method comprising:
cyclically exposing a substrate to a plurality of exposure cycles including exposures to reactants including a Hf precursor, H₂O, ozone, and a Zr precursor to form a layer of HfZrO, wherein at least one of the exposure cycles includes exposures to both H₂O and ozone.

12. The method of Example 11, wherein the at least one of the exposure cycles does not include an intervening exposure to the Hf precursor or the Zr precursor between exposures to H₂O and ozone.

13. The method of Example 12, wherein the at least one of the exposure cycles includes the exposure to H₂O is followed by the exposure to ozone.

14. The method of Example 13, wherein the at least one of the exposure cycles comprises sequential exposures to the Hf precursor, followed by H₂O, followed by ozone, followed by the Zr precursor, followed by H₂O, followed by ozone.

15. The method of Example 11, wherein each exposure to ozone comprises an exposure to a mixture of ozone and O₂, wherein a ratio of ozone to O₂ by volume substantially exceeds 4%.

16. The method of Example 11, wherein the method comprises a thermal deposition that forms the ferroelectric layer without aid of a plasma.

17. The method of Example 16, wherein the method is performed at a substrate temperature of 150-350 °C.

18. The method of Example 11, wherein the layer of HfZrO is oxygen deficient and expressed by a chemical formula HfₓZr₁₋ₓO_{2-y}, wherein each of x and y is greater than zero.

19. The method of Example 18, wherein y is greater in a first region of the layer of HfZrO closer to the substrate relative to a second region of the layer of HfZrO farther away from the substrate relative to the first region.

20. A method of forming a ferroelectric layer comprising Hf and Zr for a semiconductor device, the method comprising:
providing a substrate in a reactor chamber configured to deliver a Hf precursor, H₂O, ozone, and a Zr precursor, wherein at least H₂O and ozone are configured to be delivered through separate lines connected to the reactor chamber; and
cyclically exposing the substrate to a plurality of exposure cycles including exposures to reactants including a Hf precursor, H₂O, ozone, and a Zr precursor to form a layer of HfZrO.

21. The method of Example 20, wherein walls of the reactor chamber and the separate lines are not heated to a temperature exceeding 150 °C.

22. The method of Example 20, wherein the reactor chamber is a thermal reactor chamber that does not sustain a plasma.

23. The method of Example 22, wherein the reactor chamber is configured to heat the substrate at a temperature of 150-350 °C.

24. The method of Example 20, wherein cyclically exposing the substrate comprises:
exposing the substrate to a plurality of first exposure cycles each including exposures to a Hf precursor, H₂O and a Zr precursor to form a first layer of HfZrO; and
exposing the substrate to a plurality of second exposure cycles each including exposures to the Hf precursor, ozone and the Zr precursor to form a second layer of HfZrO over the first layer of HfZrO,

25. The method of Example 24, wherein the first and second layers of HfZrO are formed in situ in the reactor chamber.

26. The method of Example 25, wherein each of the first exposure cycles comprises sequential exposures to the Hf precursor, followed by H₂O, followed by the Zr precursor, followed by H₂O.

27. The method of Example 26, wherein each of the second exposure cycles comprises sequential exposures to the Hf precursor, followed by the ozone, followed by the Zr precursor, followed by ozone.

28. The method of Example 28, wherein each exposure to ozone comprises an exposure to a mixture of ozone and O₂, wherein a ratio of ozone to O₂ by volume substantially exceeds 4%.

29. The method of Example 20, wherein at least one of the exposure cycles includes exposures to both H2O and ozone.

30. The method of Example 30, wherein the at least one of the exposure cycles does not include an intervening exposure to the Hf precursor or the Zr precursor between exposures to H₂O and ozone.

31. The method of Example 30, wherein the at least one of the exposure cycles includes the exposure to H₂O is followed by the exposure to ozone.

32. The method of Example 31, wherein the at least one of the exposure cycles comprises sequential exposures to the Hf precursor, followed by H₂O, followed by ozone, followed by the Zr precursor, followed by H2O, followed by ozone.

33. The method of Example 20, wherein the layer of HfZrO is oxygen deficient and expressed by a chemical formula HfₓZr₁₋ₓO_{2-y}, wherein each of x and y is greater than zero.

34. The method of Example 33, wherein y is greater in a first region of the layer of HfZrO closer to the substrate relative to a second region of the layer of HfZrO farther away from the substrate relative to the first region.

35. A method of forming a metal oxide by cyclic vapor deposition, the method comprising:
providing a substrate comprising a surface comprising a metallic or semiconducting material;
exposing the substrate to a plurality of first exposure cycles each including one or more first metal precursors and H₂O to form a first oxide layer; and
exposing the substrate to a plurality of second exposure cycles each including one or more second metal precursors and O₃ to form a second oxide layer.

36. The method of Example 35, wherein the one or more first metal precursors comprises a Hf precursor.

37. The method of Example 35, wherein the one or more first metal precursors comprises a Zr precursor.

38. The method of Example 35, wherein the one or more second metal precursors comprises a Hf precursor.

39. The method of Example 35, wherein the one or more second metal precursors comprises a Zr precursor.

40. The method of Example 35, wherein the one or more first metal precursors comprises a Hf precursor and a Zr precursor.

41. The method of Example 35, wherein the one or more second metal precursors comprises a Hf precursor and a Zr precursor.

42. The method of Example 35, wherein:
exposing the substrate to the first exposure cycles each includes exposures to a Hf precursor, H₂O and a Zr precursor to form a first layer of HfZrO; and
exposing the substrate to the second exposure cycles each includes exposures to the Hf precursor, ozone and the Zr precursor to form a second layer of HfZrO over the first layer of HfZrO,
wherein the first and second layers of HfZrO are formed in situ in a same reactor chamber.

43. The method of any one of Examples 35-42, wherein each of the first exposure cycles comprises sequential exposures to the Hf precursor, followed by H₂O, followed by the Zr precursor, followed by H₂O.

44. The method of any one of Examples 35-43, wherein each of the second exposure cycles comprises sequential exposures to the Hf precursor, followed by the ozone, followed by the Zr precursor, followed by ozone.

45. The method of any one of Examples 35-44, wherein each exposure to ozone comprises an exposure to a mixture of ozone and water, wherein a ratio of ozone to water by volume substantially exceeds 4%.

46. The method of any one of Examples 35-45, wherein a ratio of a number (M) of the second exposure cycles to a number (N) of the first exposure cycles exceeds 3.

47. The method of any one of Examples 35-46, wherein the first layer of HfZrO is formed directly on a Si surface or a TiN surface.

48. The method of any one of Examples 35-47, wherein the method comprises a thermal deposition that forms the ferroelectric layer without aid of a plasma.

49. The method of any one of Examples 35-46, wherein the method is performed at a substrate temperature of 150-350 °C.

50. The method of any one of Examples 35-49, wherein each of the first and second layers of HfZrO is oxygen deficient and expressed by a chemical formula HfₓZr₁₋ₓO_{2-y}, wherein each of x and y is greater than zero.

51. The method of Example 50, wherein y is greater in the first layer of HfZrO relative to the second layer of HfZrO.

52. A method of forming a metal oxide by cyclic vapor deposition, the method comprising:
providing a substrate comprising a surface comprising a metallic or semiconducting material;
exposing the substrate to one or more first exposure cycles each including a first metal (M1) precursor, H₂O and ozone; and
exposing the substrate to one or more second exposure cycles each including a second metal (M2) precursor and H₂O and ozone.

53. The method of Example 52, wherein the M1 precursor comprises a Hf precursor.

54. The method of Example 52, wherein the M2 precursors comprises a Zr precursor.

55. The method of Example 52, wherein the M1 comprises a Hf precursor and the M2 precursor comprises a Zr precursor.

56. The method of any one of Examples 52-55, wherein the method comprises forming a layer of HfZrO by:
exposing the substrate to the one or more first exposure cycles comprises exposing the substrate to the M1 precursor including a Hf precursor, H₂O and ozone, and
exposing the substrate to the one or more second exposure cycles comprises exposing the substrate to the M2 precursor including a Zr precursor, H₂O and ozone.

57. The method of any one of Examples 52-56, wherein the at least one of the first or second exposure cycles does not include an intervening exposure to the Hf precursor or the Zr precursor between exposures to H₂O and ozone.

58. The method of any one of Examples 52-57, wherein the at least one of the exposure cycles includes the exposure to H₂O is followed by the exposure to ozone.

59. The method of any one of Examples 52-58, wherein the at least one of the exposure cycles comprises sequential exposures to the Hf precursor, followed by H₂O, followed by ozone, followed by the Zr precursor, followed by H₂O, followed by ozone.

60. The method of any one of Examples 52-59, wherein the method comprises a thermal deposition that forms the ferroelectric layer without aid of a plasma.

61. The method of any one of Examples 52-60, wherein the method is performed at a substrate temperature of 150-350 °C.

62. The method of any one of Examples 52-61, wherein the method forms a layer of HfZrO that is oxygen deficient and expressed by a chemical formula HfₓZr₁₋ₓO_{2-y}, wherein each of x and y is greater than zero.

63. The method of Example 62, wherein y is greater in a first region of the layer of HfZrO closer to the substrate relative to a second region of the layer of HfZrO farther away from the substrate relative to the first region.

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

1. A method of forming a ferroelectric layer comprising Hf and Zr for a semiconductor device, the method comprising:
exposing a substrate to a plurality of first exposure cycles each including exposures to a Hf precursor, H₂O and a Zr precursor to form a first layer of HfZrO; and
exposing the substrate to a plurality of second exposure cycles each including exposures to the Hf precursor, ozone and the Zr precursor to form a second layer of HfZrO over the first layer of HfZrO,
wherein the first and second layers of HfZrO are formed in situ in a same reactor chamber.

2. The method of claim 1, wherein each of the first exposure cycles comprises sequential exposures to the Hf precursor, followed by H₂O, followed by the Zr precursor, followed by H₂O.

3. The method of claim 2, wherein each of the second exposure cycles comprises sequential exposures to the Hf precursor, followed by the ozone, followed by the Zr precursor, followed by ozone.

4. The method of claim 3, wherein each exposure to ozone comprises an exposure to a mixture of ozone and water, wherein a ratio of ozone to water by volume substantially exceeds 4%.

5. The method of claim 2, wherein a ratio of a number (M) of the second exposure cycles to a number (N) of the first exposure cycles exceeds 3.

6. The method of claim 1, wherein the first layer of HfZrO is formed directly on a Si surface or a TiN surface.

7. The method of claim 1, wherein the method comprises a thermal deposition that forms the ferroelectric layer without aid of a plasma.

8. The method of claim 7, wherein the method is performed at a substrate temperature of 150-350 °C.

9. The method of claim 1, wherein each of the first and second layers of HfZrO is oxygen deficient and expressed by a chemical formula HfₓZr₁₋ₓO_{2-y}, wherein each of x and y is greater than zero.

10. The method of claim 9, wherein y is greater in the first layer of HfZrO relative to the second layer of HfZrO.

11. A method of forming a ferroelectric layer comprising Hf and Zr for a semiconductor device, the method comprising:
cyclically exposing a substrate to a plurality of exposure cycles including exposures to reactants including a Hf precursor, H₂O, ozone, and a Zr precursor to form a layer of HfZrO, wherein at least one of the exposure cycles includes exposures to both H₂O and ozone.

12. The method of claim 11, wherein the at least one of the exposure cycles does not include an intervening exposure to the Hf precursor or the Zr precursor between exposures to H₂O and ozone.

13. The method of claim 12, wherein the at least one of the exposure cycles includes the exposure to H₂O is followed by the exposure to ozone.

14. The method of claim 13, wherein the at least one of the exposure cycles comprises sequential exposures to the Hf precursor, followed by H₂O, followed by ozone, followed by the Zr precursor, followed by H₂O, followed by ozone.

15. The method of claim 11, wherein each exposure to ozone comprises an exposure to a mixture of ozone and O₂, wherein a ratio of ozone to O₂ by volume substantially exceeds 4%.

16. The method of claim 11, wherein the method comprises a thermal deposition that forms the ferroelectric layer without aid of a plasma.

17. The method of claim 16, wherein the method is performed at a substrate temperature of 150-350 °C.

18. The method of claim 11, wherein the layer of HfZrO is oxygen deficient and expressed by a chemical formula HfₓZr₁₋ₓO_{2-y}, wherein each of x and y is greater than zero.

19. The method of claim 18, wherein y is greater in a first region of the layer of HfZrO closer to the substrate relative to a second region of the layer of HfZrO farther away from the substrate relative to the first region.

20-34. (canceled)

35. The method of claim 1, wherein the same reactor chamber is configured to deliver the Hf precursor, H₂O, ozone, and the Zr precursor, wherein at least H₂O and ozone are configured to be delivered through separate lines connected to the reactor chamber.
